(19) United States
(12) Patent Application Publication
(10) Pub. No.: US 2013/0069652 A1
(43) Pub. Date: Mar. 21, 2013

(54) RF COIL AND MAGNETIC RESONANCE IMAGING DEVICE

(71) Applicants: Yosuke Otake, Mitaka (JP); Yoshihisa Soutome, Tokyo (JP); Yukio Kaneko, Kawaguchi (JP); Yoshitaka Bito, Kokubunji (JP); Hisaaki Ochi, Kodaira (JP); Koji Hirata, Kasukabe (JP)

(72) Inventors: Yosuke Otake, Mitaka (JP); Yoshihisa Soutome, Tokyo (JP); Yukio Kaneko, Kawaguchi (JP); Yoshitaka Bito, Kokubunji (JP); Hisaaki Ochi, Kodaira (JP); Koji Hirata, Kasukabe (JP)

(21) Appl. No.: 13/522,928

(22) PCT Filed: Jan. 25, 2011
(86) PCT No.: PCT/JP2011/051345

§ 371 Date: Nov. 30, 2012

(30) Foreign Application Priority Data
Mar. 31, 2010 (JP) 2010-080563

(51) Int. Cl. G01R 33/34

(52) U.S. Cl. 324/322

(57) ABSTRACT

There is a provided a technology of receiving a magnetic resonance signal highly sensitively and with a uniform sensitivity distribution in an RF coil of an MRI device which is an RF coil including a switch circuit of switching a circuit configuration. The RF coil of the MRI device of the present invention includes a switch circuit of switching a circuit configuration. Also, the switch circuit switches the circuit configuration by being driven by a control signal received by wireless. For that purpose, the switch circuit includes an antenna of receiving the control signal and a conversion circuit of converting an alternating current voltage received into a direct current voltage.

### TECHNICAL FIELD

The present invention relates to a technology of (MRI: Magnetic Resonance Imaging). The present invention particularly relates to a technology of changing a frequency characteristic of an RF coil which transmits and receives an (RF: Radio Frequency) signal.

### BACKGROUND ART

An MRI device is a medical imaging diagnostic device which produces a magnetic resonance by transmitting an RF magnetic field to a nucleus in an arbitrary section that traverses a test subject, and obtaining a tomographic image in the section from a magnetic resonance signal generated thereby. Generally, a magnetic resonance signal of hydrogen nucleus (¹H) is used.

Irradiation (transmission) of an RF magnetic field and reception of a magnetic resonance frequency signal are carried out by an RF coil. Generally, the RF coil is a resonance circuit which connects a loop configured by a conductor and a capacitor in parallel with each other or in series with each other. A resonance frequency of the resonance circuit is adjusted to a frequency the same as a magnetic resonance frequency f₀ of a nucleus by adjusting a value of the capacitor. The RF coil transmits the RF magnetic field and receives the magnetic resonance signal efficiently by configuring the resonance circuit.

However, there is a case where a frequency characteristic of an RF coil is changed over time for the purpose of preventing a magnetic coupling between RF coils, or receiving magnetic resonance signals of plural nuclei by a single coil.

For example, there is a case where in order to transmit and receive an RF magnetic field by an optimum shape and an optimum arrangement, the transmission and the reception are carried out by separate exclusive RF coils (transmit and receive type). In the case of the transmit and receive type, resonance frequencies of the both RF coils are adjusted to be the same magnetic resonance frequency f₀, and therefore, a magnetic coupling is generated between the both RF coils. Decoupling (removal of magnetic coupling) is carried out generally in order to avoid destruction and a reduction in a sensitivity by the magnetic coupling. The decoupling is realized by, for example, inserting magnetic coupling prevention circuits respectively to the both RF coils. The magnetic coupling prevention circuits prevent the magnetic coupling by changing frequency characteristics of a transmit RF coil and a receive RF coil in transmitting an RF magnetic field and in receiving a magnetic resonance signal (refer to, for example, Patent Literature 1 and Patent Literature 2).

A general magnetic coupling prevention circuit uses a PIN diode as a switch element. A circuit configuration (frequency characteristic) of an RF coil is switched and an operation of the RF coil is changed by making a PIN diode ON/OFF. As shown by FIG. 17, a magnetic coupling prevention circuit 950 is integrated to an RF coil 900. The magnetic coupling prevention circuit 950 is a circuit which connects a capacitor 911 that is inserted to a conductor 902 of the RF coil (for example, surface coil) 900 in parallel with a circuit that connects a PIN diode 930 and an inductor 920 in series with each other. Incidentally, a capacitor 910 is inserted to the surface coil 900 other than the capacitor 911.

The PIN diode 930 is driven by a DC power supply 906 which is connected to both ends of the PIN diode 930 via a cable 904. The cable 904 is inserted with a choke coil 429 which cuts off a radio frequency signal. When the PIN diode 930 is made ON by the DC power supply 960, the magnetic coupling prevention circuit 950 prevents the magnetic coupling by the following two effects. The first effect is achieved by changing a frequency characteristic of the RF coil 900. When the PIN diode 930 is made ON, the inductor 920 becomes effective. Thereby, an inductance of the RF coil 900 is changed, and therefore, a resonance frequency of the RF coil 900 is changed. In a case where a frequency characteristic of either one RF coil of a transmit RF coil or a receive RF coil is changed, the resonance frequencies do not coincide with each other, and therefore, the magnetic coupling is reduced. The second effect is achieved by that the inductor 920 and the capacitor 911 configure a parallel circuit which brings about high impedance (high resistance). Generally, an impedance (resistance) of a parallel resonance circuit of an inductor and a capacitor brings about a high impedance at the resonance frequency. Therefore, the inductor 920 and the capacitor 911 are adjusted to resonate at a frequency the same as a resonance frequency of the RF coil 900. Then, when the PIN diode 930 is made ON, the magnetic coupling prevention circuit 950 shows a high resistance against a radio frequency of a magnetic resonance frequency. This is equivalent to that a high resistance is inserted into the RF coil 900. Therefore, a current having the magnetic resonance frequency hardly flows in the RF coil 900 which is adjusted to resonate at the magnetic resonance frequency. Therefore, the magnetic coupling is not produced.

### CITATION LIST

### Patent Literatures

Patent Literature 1: Japanese Patent Publication No. 3655881

Patent Literature 2: Japanese Patent Publication No. 3836416

### SUMMARY OF INVENTION

### Technical Problem

In a case where switching means starting from the PIN diode are used for changing the frequency characteristic by switching the circuit configuration of the RF coil as in the magnetic coupling preventing circuit described above, the DC power supply is needed for driving the switching means. The DC power supply is installed ordinarily at a position of being remote from the RF coil, and is connected to switching means of the RF coil by the cable.

In a case where the circuit configuration of the RF coil is switched by the switching means which needs to be driven by the DC power supply, the cable for transmitting a current is needed. The cable is easy to be magnetically coupled with the RF coil. Therefore, there frequently poses a problem by a reduction in a sensitivity or a nonuniformity in the sensitivity of the RF coil owing to the cable. Particularly, in recent years, the magnetic coupling of the cable and the RF coil is easy to be produced in accordance with high magnetic field formation or multi-channel formation of an MRI device.

The present invention has been carried out in view of the situation described above and it is an object thereof to provide a technology of an RF coil of an MRI device which includes a switch circuit of switching a circuit configuration for receiving a magnetic resonance signal highly sensitively and with a uniform sensitivity distribution.

### Solution to Problem

An RF coil of an MRI device of the present invention includes a switch circuit of switching a circuit configuration. Also, the switch circuit switches the circuit configuration by being driven by a control signal which is received by wireless. For that purpose, the switch circuit includes an antenna of receiving the control signal, a conversion circuit of converting an AC voltage received into a DC voltage, and switching means.

Specifically, the present invention is an RF coil of a magnetic resonance imaging device which includes a receiving antenna of receiving a control signal, a switch circuit which is driven by the control signal received by the receiving antenna, and a resonance circuit which inserts a capacitor to a loop configured by a conductor, the RF coil being featured in that the switch circuit is connected to the resonance circuit, and a resonance frequency of the resonance circuit differs by presence or absence of receiving the control signal. Also, the switch circuit is connected to the resonance circuit via the switching means configuring the switch circuit.

Also, the present invention is an RF coil system of a magnetic resonance imaging device, the RF coil system including a transmit RF coil of transmitting a radio frequency signal, and a receive RF coil of receiving a magnetic resonance signal, the receive RF coil being the RF coil described above, the RF coil system being featured in that the switch circuit brings the receive RF coil into an open state when the transmit RF coil transmits the radio frequency signal.

Also, the present invention is a magnetic resonance imaging device including static magnetic field configuring means for configuring a static magnetic field, gradient magnetic field applying means for applying a gradient magnetic field, a transmit RF coil of transmitting a radio frequency signal, a receive RF coil of receiving a magnetic resonance signal generated from a test subject by applying the radio frequency magnetic field, and controlling means for controlling operations of the gradient magnetic field applying means, the transmit RF coil, and the receive RF coil, the magnetic resonance imaging device being featured in that the receive RF coil is the RF coil described above.

### Advantageous Effects of Invention

According to the present invention, in an RF coil of an MRI device, and in an RF coil including switching means for switching a circuit configuration by a control signal, a magnetic resonance signal can be received highly sensitively and with a uniform sensitivity distribution.

### BRIEF DESCRIPTION OF DRAWINGS

FIGS. 1(a) and 1(b) are outlook views of an MRI device according to a first embodiment.

FIG. 2 is a block diagram of the MRI device according to the first embodiment.

FIG. 3(a) is an explanatory view for explaining a configuration of an RF coil portion according to the first embodiment, and FIG. 3(b) is a sequence diagram for explaining an imaging sequence of the first embodiment.

FIG. 4(a) is an explanatory diagram for explaining a control signal transmitter according to the first embodiment, and FIG. 4(b) is a circuit diagram of a receive RF coil according to the first embodiment.

FIG. 5(a) is a circuit diagram of a transmit RF coil according to the first embodiment, and FIG. 5(b) is a diagram for explaining a circuit of a magnetic coupling prevention circuit of the transmit RF coil according to the first embodiment.

FIGS. 6(a) and 6(b) are diagrams for explaining circuits of modified examples of conversion circuits according to the first embodiment.

FIG. 7 is a circuit diagram of a saddle coil which is a modified example of the first embodiment.

FIG. 8 is a circuit diagram of a butterfly coil which is a modified example of the first embodiment.

FIG. 9 is a circuit diagram of a solenoid coil which is a modified example of the first embodiment.

FIG. 10(a) is a circuit diagram of a birdcage coil which is a modified example of the first embodiment, and FIG. 10(b) is a circuit diagram of a switch circuit thereof. Also, FIG. 10(c) is a circuit diagram of a birdcage coil which is a modified example of the first embodiment, and FIG. 10(d) is a circuit diagram of a switch circuit thereof.

FIG. 11 is a circuit diagram of an array coil which is a modified example of the first embodiment.

FIG. 12(a) is a circuit diagram of a QD coil which is a modified example of the first embodiment, and FIG. 12(b) is an explanatory diagram for explaining a direction of a magnetic field of the QD coil.

FIG. 13 is a block diagram for explaining connection between the QD coil which is a modified example of the first embodiment, and a receiver.

FIG. 14(a) is an explanatory view for explaining a configuration of an RF coil portion according to a second embodiment, and FIG. 14(b) is a sequence diagram for explaining an imaging sequence according to the second embodiment.

FIG. 15 is a circuit diagram of a receive RF coil according to the second embodiment.

FIG. 16(a) is a circuit diagram of a transmit RF coil according to the second embodiment, and FIG. 16(b) is a diagram for explaining a circuit of a magnetic coupling prevention circuit thereof.

FIG. 17 is a circuit diagram of an RF coil of a background art.

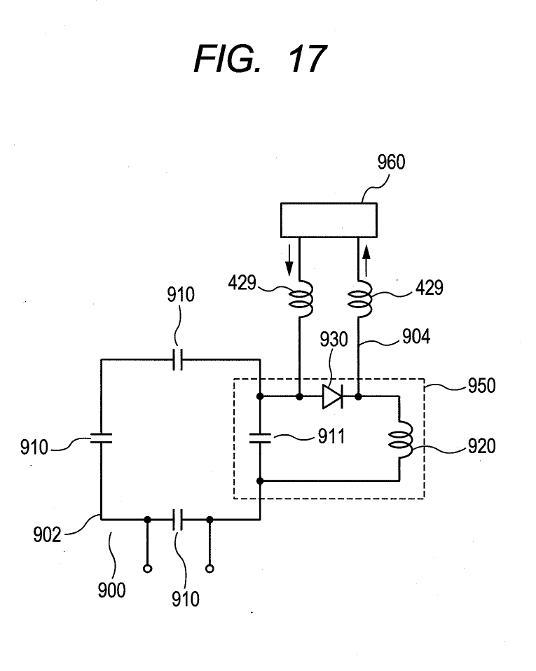

### DESCRIPTION OF EMBODIMENTS

### First Embodiment

An explanation will be given of a first embodiment to which the present invention is applied. According to the embodiment, in an MRI device (transmit and receive type) which separately includes a transmit RF coil and a receive RF coil, a switch circuit which changes a circuit configuration of the receive

RF coil by a control signal that is transmitted by wireless is used as a magnetic coupling prevention circuit which prevents a magnetic coupling with the transmit RF coil. In the following, in all of the drawings for explaining embodiments of the present invention, portions having the same functions are attached with the same notations, and a repetitive explanation thereof will be omitted.

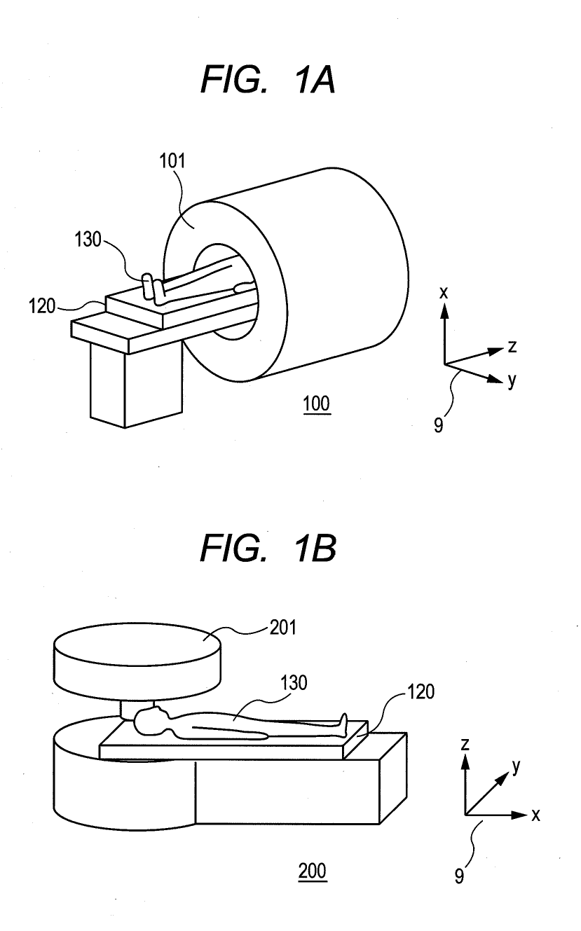

First, an explanation will be given of a total configuration of the MRI device according to the present embodiment. FIG. 1 illustrates outlook views of the MRI device according to the present embodiment, and in the drawings, a z axis direction of a coordinate system 9 is a direction of a static magnetic field. In the following, the same goes with all of the drawings of the present specification. FIG. 1(a) shows an MRI device 100 including a horizontal magnetic field type magnet 101. A test subject 130 is inserted to an imaging space at inside of a bore of the magnet 101 in a state of being laid on a table 120, and is imaged. FIG. 1(b) shows an MRI device 200 including a vertical magnetic field type magnet 201. The test subject 130 is inserted to an imaging space between a pair of up and down magnets 201 in a state of being laid on the table 120 and is imaged. According to the present embodiment, either of the horizontal magnetic field type and the vertical magnetic field type will do. An explanation will be given as follows by taking an example of the horizontal magnetic field type MRI device 100.

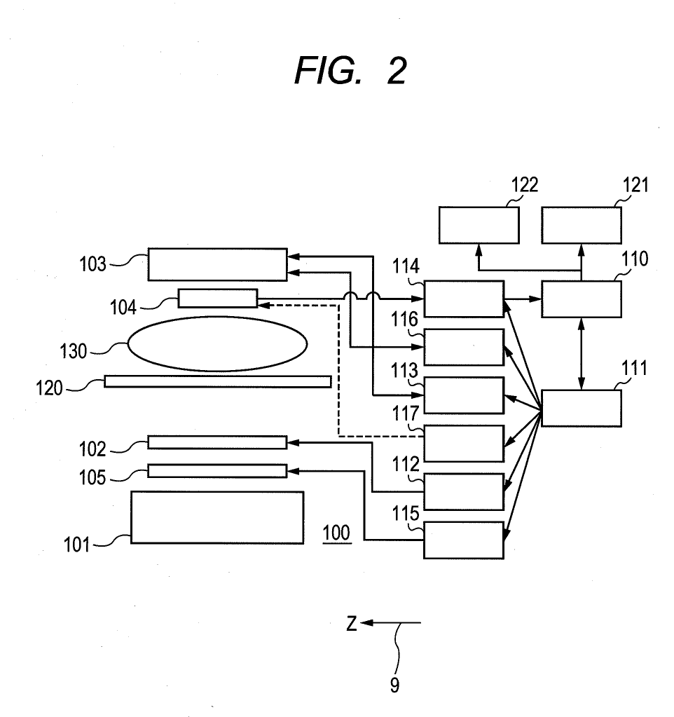

FIG. 2 is a block diagram showing an outline configuration of the MRI device 100. As shown in the drawing, the MRI device 100 includes the horizontal magnetic field type magnet 101, a gradient coil 102 which generates a gradient magnetic field, a transmit RF coil 103 which transmits an RF magnetic field to the test subject 130, a receive RF coil 104 which receives a signal from the test subject 130, a gradient magnetic field power supply 112, an RF magnetic field generator 113, a receiver 114, a DC power supply 116, a sequencer 111, a computer 110, and the table 120 which mounts the test subject.

The sequencer 111 performs a control in accordance with a designation from the computer 110 such that respective portions are operated at timings and with strengths which are previously programmed. That is, the sequencer 111 sends instructions to the gradient magnetic field power supply 112, the RF magnetic field generator 113, and the DC power supply 116. In accordance with the instruction, the gradient magnetic field power supply 112 makes the gradient magnetic field coil 102 generate a gradient magnetic field. Also, the RF magnetic field generator 113 generates an RF magnetic field and transmits the RF magnetic field from the transmit RF coil 103. Furthermore, the DC power supply 116 sends a current to the transmit RF coil 103 which is connected by a cable to be brought into an open state.

A magnetic resonance signal which is generated from the test subject 103 by transmitting the RF magnetic field from the transmit RF coil 103 to the test subject 130 is detected by the receive RF coil 104. The detected signal is subjected to detection at the receiver 114. A magnetic resonance frequency which becomes a reference of the detection at the receiver 114 is reset by the sequencer 111. The signal as detected is sent to the computer 110 by way of an A/D conversion circuit, where a signal processing of an image reconstruction or the like is carried out. A result thereof is displayed on a display 121. The signal subjected to the detection and a measurement condition are preserved in a storage medium 122 as necessary.

According to the present embodiment, the receive RF coil 104 is prevented from being magnetically coupled with the transmit RF coil 103 by sending a control signal by a wireless communication. For that purpose, the MRI device 100 of the present embodiment includes a control signal transmitter 117 in addition to the configuration described above. The control signal transmitter 117 sends a control signal to the receive RF coil 104 by a wireless communication in accordance with an instruction from the sequencer 111 to bring the receive RF coil 104 into an open state.

Incidentally, when it is necessary to adjust a static magnetic field uniformity, a shim coil 105 is driven by a shim power supply 115 which is operated in accordance with an instruction from the sequencer 111.

An explanation will be given as follows of details of an RF coil portion 500 including the transmit RF coil 103, the receive RF coil 104, the RF magnetic field generator 113, the receiver 114, the DC power supply 116, and the control signal transmitter 117. According to the present embodiment, an explanation will be given by taking an example of a case of using a birdcage coil 300 having a birdcage shape for the transmit RF coil 103, and using a surface coil 400 having a loop shape for the receive RF coil 104.

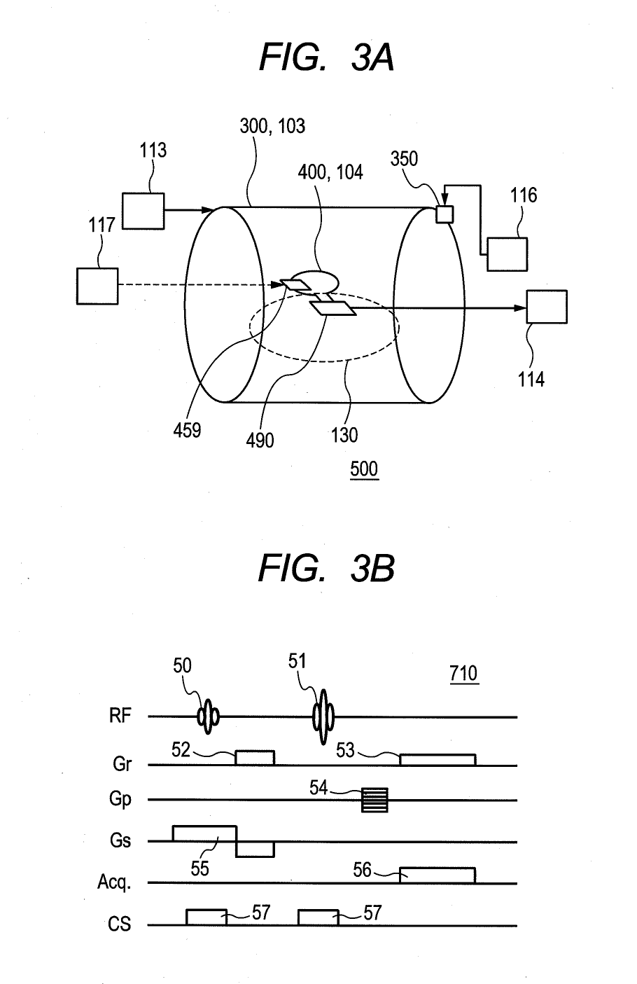

First, an explanation will be given of a configuration of the RF coil portion 500, the RF magnetic field, the gradient magnetic field, and a timing of generating the control signal according to the present embodiment in reference to FIG. 3.

FIG. 3(a) is a block diagram for explaining a connection of the RF coil portion 500 according to the present embodiment. As shown in the drawing, the birdcage coil 300 which is used as the transmit RF coil 103 of the present embodiment transmits the RF magnetic field which is generated by the RF magnetic field generator 113. The birdcage coil 300 is inserted with a magnetic coupling prevention circuit 350 which brings the birdcage coil 300 into an open state at a timing of receiving a magnetic resonance signal in order to prevent the magnetic coupling with the receive RF coil 104.

The magnetic field coupling prevention circuit 350 is a magnetic field prevention circuit of a conventional type which uses the DC power supply. The magnetic coupling prevention circuit 350 is inserted to a conductor of the birdcage coil 300. The inserted magnetic coupling prevention circuit 350 is driven by the DC power supply 116, and prevents the magnetic coupling of the birdcage coil 300 and the surface coil 400.

The loop coil (surface coil) 400 which is used as the receive RF coil 104 is inserted with a switch circuit 459. A magnetic resonance signal which is received at the surface coil 400 is connected to the receiver 114 by way of a signal processing circuit 490 including a balun or a pre amplifier.

The switch circuit 459 according to the present embodiment is driven by a control signal which is transmitted from the control signal transmitter 117 by wireless. The driven switch circuit 459 changes a circuit configuration of the surface coil 400, brings the surface coil 400 into the open state, and prevents the magnetic coupling with the transmit RF coil 103. According to the present embodiment, the control signal is transmitted to the switch circuit 459 when the RF magnetic field is transmitted in order to prevent the magnetic coupling of the transmit RF coil 103 and the surface coil 400 when the RF magnetic field is transmitted.

FIG. 3(b) is a timing chart of an SE (Spin Echo) method that is one of imaging methods in MRI. There is shown a timing at which the control signal transmitter 117 transmits the control signal to the switch circuit 459 in reference to the drawing. Notation ‘RF’ designates a timing of transmitting a radio frequency wave by the transmit RF coil 103. Notations ‘Gr’, ‘Gp’, and ‘Gs’ designate timings of generating gradient magnetic fields by the gradient coil 102. Notation ‘Acq.’ designates a timing of carrying out data acquisition by the receive RF coil 104. Notation ‘CS’ designates a timing of transmitting a control signal to the switch circuit 459 by the control signal transmitter 117. A specific explanation will be given as follows.

First, an explanation will be given of the imaging method of the SE method. First, a 90° pulse 50 is transmitted while applying a slice selective magnetic field 55. Thereafter, a dephase magnetic field 52 is applied. Next, a 180° pulse 51 is transmitted. Thereafter, an encode magnetic field 54 is applied. Finally, a lead-out magnetic field 53 is applied to subject the generated magnetic field resonance signal to data acquisition 56. The above-described is a timing chart of the SE method. Under such timings, the control signal (CS) 57 is transmitted when the 90° pulse 50 is transmitted and when the 180° pulse 51 is transmitted.

Incidentally, a timing of transmitting the control signal (CS) is not limited to the above-described. So far as the control signal (CS) is transmitted when the RF signal is transmitted (ON state), and the control signal (CS) is not transmitted when the RF signal is received (OFF state), any timing waveform will do. For example, in the timing chart shown in FIG. 3(b), the control signal (CS) may continuously be transmitted during a time period from transmitting the 90° pulse 50 to transmitting the 180° pulse 51.

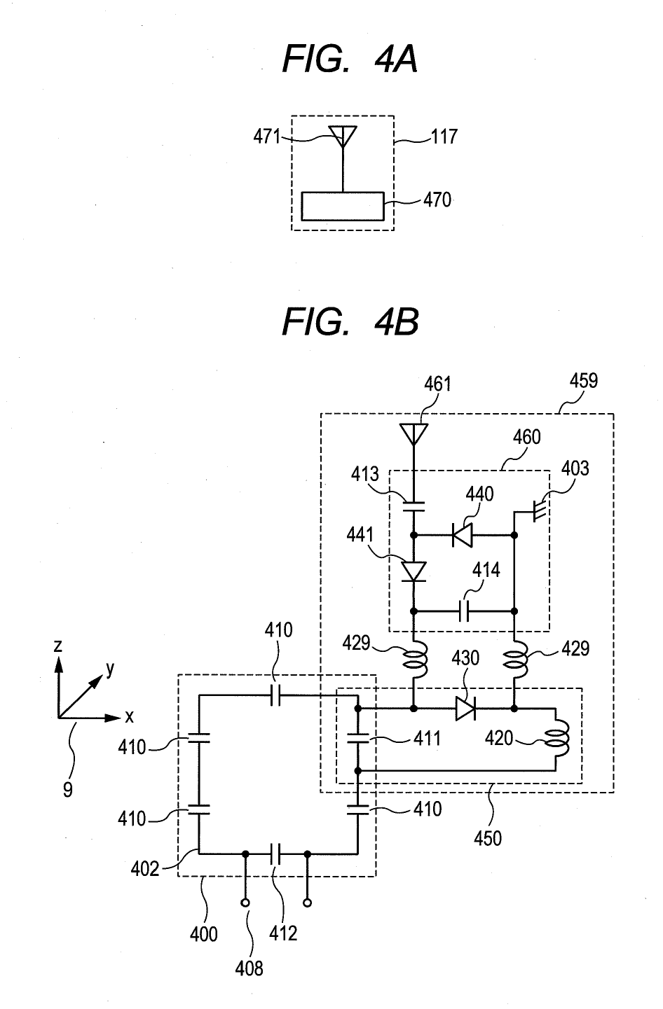

Next, an explanation will be given of configurations of the control signal transmitter 117 and the receive RF coil 104 of the present embodiment which is inserted with the switch circuit 459 in reference to FIG. 4.

FIG. 4(a) is a diagram for explaining the control signal transmitter 117 according to the present embodiment. The control signal transmitter 117 of the present embodiment includes a control signal transmitting antenna 471 and a control signal generator 470. The control signal generator 470 generates a control signal by a designation of the sequencer 111 at a timing which is determined by an imaging sequence 710 described above. The control signal transmitting antenna 471 transmits the control signal which is generated by the control signal generator 470.

As the control signal transmitting antenna 471, for example, a half-wave whip antenna is used. As a tuning frequency, there is used a high frequency which differs from the magnetic resonance frequency by 20% or more and which can downsize the antenna comparatively easily in order to prevent interference. According to the present embodiment, the tuning frequency is set to 400 MHz. Incidentally, the tuning frequency of the control signal transmitter 117 is not limited thereto.

The control signal transmitter 117 is installed at, for example, an entry of a tunnel of the horizontal magnetic field type magnet 101. Incidentally, a position of installing the control signal transmitter 117 is not limited thereto. The installing position may be a position at which the control signal transmitter 117 is not shielded by the magnet 101 and a radio wave can arrive at a control signal receiving antenna which configures the receive RF coil 104. For example, the position may be at inside of the table 120 which mounts the test subject 130.

FIG. 4(b) is a circuit diagram of the receive RF coil 104 according to the present embodiment. As described above, the receive RF coil 104 is configured by inserting the switch circuit 459 to the surface coil 400.

The surface coil 400 is a parallel resonant circuit in which a matching capacitor (C_{M}) 412 is connected in parallel with a series resonant circuit in which a conductor 402 having a loop shape is inserted with four of capacitors (a capacitance of which is designated by notation C_{D}) 410 and a capacitor (C_{D}) 411 at equal intervals. The surface coil 400 is connected to the signal processing circuit 490 by way of a port 408. Incidentally, the capacitors 410, 411, and 412 are adjusted to be resonated at a magnetic resonance frequency of a nucleus which is received by the surface coil 400.

The surface coil 400 configures the parallel resonant circuit. Generally, a resonance frequency f_{P} of a parallel resonant circuit by an inductor (L) and a capacitor (C) is represented by Equation (1).

$$\begin{matrix}[ Equation 1 ] & \\ {f}_{p} = \frac{1}{2 π} \sqrt{\frac{1}{LC}} & ( 1 )\end{matrix}$$

Therefore, a resonance frequency fₛ of the surface coil 400 is represented by Equation (2) as follows.

$$\begin{matrix}[ Equation 2 ] & \\ {f}_{s} = \frac{1}{2 π} \sqrt{\frac{{C}_{M} + {C}_{A}}{{L}_{C} {C}_{A}^{2} {C}_{M}}} & ( 2 )\end{matrix}$$

Incidentally, notation C_{A} designates a synthesized capacitance of the four capacitors (C_{D}) 410 and the capacitor (C_{D}) 411. Also, notation L_{C} designates an inductance of the conductor 402 having the loop shape.

Values of the respective capacitors 410, 411, and 412 of the surface coil 400 are adjusted to satisfy Equation (2) in order to resonate the surface coil 400 at the received magnetic resonance frequency f₀ of the nucleus, make the surface coil 400 function as the receive RF coil 104, and match an impedance of the surface coil 400 with an impedance of the port 408.

The switch circuit 459 includes a control signal receiving antenna 461 which receives the control signal that is transmitted from the control signal transmitter 117, a conversion circuit 460 which converts the control signal received by the control signal receiving antenna 461 into a DC voltage, a PIN diode 430, an inductor 420, and a choke coil 429 which prevents an RF signal from flowing in.

The conversion circuit 460 is configured by rectifier elements and capacitors. The conversion circuit 460 generates a DC voltage by rectifying and smoothing an AC voltage which is generated at the control signal receiving antenna 461. For converting the AC voltage into the DC voltage, for example, a half-wave double voltage rectifier circuit shown in FIG. 4(b) is used.

The half-wave double voltage rectifier circuit includes a first rectifier diode 440, a second rectifier diode 441, a first capacitor 413, and a second capacitor 414. In the first rectifier diode 440 and the second rectifier diode 441, different polarity terminals thereof are connected in series with each other. One terminal of the first capacitor 413 is connected to a connection point at which the different polarity terminals of the first rectifier diode 440 and the second rectifier diode 441 are connected to each other. The other terminal of the first capacitor 413 is connected to the control signal receiving antenna 461. The second capacitor 414 is connected in parallel with the first rectifier diode 440 and the second rectifier diode 441 which are connected in series with each other. Both ends of the second capacitor 414 are connected with the other terminals of the two choke coils 429. Incidentally, notation 403 designates the ground.

As the control signal receiving antenna 461, for example, a half-wave whip antenna is used, and is adjusted to a resonance frequency the same as that of the control signal transmitting antenna 471. The control signal which is received by the control signal receiving antenna 461 is converted into a DC voltage by the conversion circuit 460.

The control signal receiving antenna 461 generates an AC voltage when the control signal receiving antenna 461 receives a radio wave which is transmitted from the control signal transmitting antenna 471. The generated AC voltage is applied to the conversion circuit as an input.

In the conversion circuit 460, when a negative voltage is applied to the capacitor 413, an electric charge is charged to the capacitor 413 via the rectifier diode 440. When a positive voltage is applied to the capacitor 413, a voltage from the control signal receiving antenna 461 and a voltage which is charged by the capacitor 413 are added, and an added voltage is outputted via the rectifier diode 441. The voltage which is obtained at this time is configured by only a half wave of an alternating current voltage. The output is smoothed by the capacitor 414 which is connected in parallel with the rectifier diode 440 and the rectifier diode 441 that are connected in series with each other to obtain a DC voltage. The DC voltage is outputted to both ends of the diode 430 via the choke coils 429 which are inserted therebetween in order to prevent an RF signal from flowing in. The choke coils 429 restrain an interference of the conversion circuit 460 and the surface coil 400.

A series circuit by the PIN diode 340 and the inductor 420 which is connected in series with the PIN diode 430 and the inductor 420 is connected in parallel with the capacitor 411 of the surface coil 400. A magnetic coupling prevention circuit 450 is configured by the PIN diode 430, the inductor 420 and the capacitor 411.

A value of the inductor 420 is adjusted such that a parallel resonant circuit which is configured by the inductor 420 along with the capacitor 411 is resonated in parallel at the received magnetic resonance frequency of the nucleus. That is, the value (L) of the inductor 420 is adjusted in accordance with Equation (1) by setting the received magnetic resonance frequency to f₀ (=fₚ), and setting the value of the capacitor 411 to C.

Generally, a parallel resonant circuit of an inductor and a capacitor has a high impedance (high resistance) at a resonance frequency. Therefore, in the circuit in which the inductor 420 is adjusted as described above, in a case where a current flows to the PIN diode 430, the PIN diode 430 is made ON, and the capacitor 411 of the surface coil 400 is resonated in parallel with the inductor 420 to be brought into a high impedance state. That is, a portion of the surface coil 400 has a high impedance, and therefore, the surface coil 400 is brought into an open state.

The PIN diode 430 is driven by a current of a DC voltage by converting the signal which is received by the control signal receiving antenna 461 into the DC voltage by the conversion circuit 460. Therefore, when the control signal 57 is received, the PIN diode 430 is made ON. A resonance frequency of the surface coil 400 is changed, and the surface coil 400 is made to have a high impedance at the magnetic resonance frequency f₀. Therefore, the surface coil 400 does not interfere with the transmit RF coil 103 (birdcage type coil 300). On the other hand, when the control signal 57 is not received, the PIN diode 430 is made OFF, and the surface coil 400 is made to function as the receive RF coil 104.

Therefore, when the control signal is transmitted at the timing at which the magnetic coupling is intended to prevent as shown by FIG. 3(b), the PIN diode 430 is made ON. Therefore, the surface coil 400 is not magnetically coupled with the birdcage type coil 300 and can transmit or receive RF.

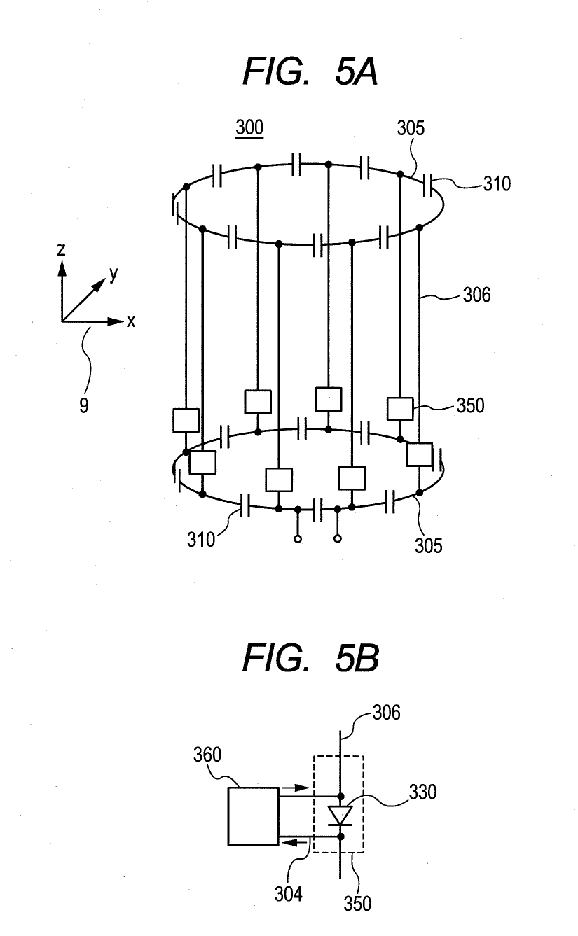

Next, an explanation will be given of a configuration of the transmit RF coil 103 of the present embodiment in reference to FIG. 5. Incidentally, a magnetic coupling prevention circuit 350 which is inserted to the transmit RF coil 103 of the present embodiment is a magnetic coupling prevention circuit of a conventional type using a DC power supply.

FIG. 5(a) is a circuit diagram of the birdcage coil 350 which is used as the transmit RF coil 103 of the present embodiment. The birdcage coil 300 includes 2 of loop conductors 305 and 8 of linear conductors 306. The two loop conductors 305 are connected by the linear conductors 306 to configure a birdcage shape. The magnetic coupling prevention circuits 350 are respectively inserted to the plural linear conductors 306 of the birdcage RF coil 300 in series therewith. The loop conductor 305 is inserted with the linear conductors 306 and capacitors 310 alternately at equal intervals.

FIG. 5(b) is a diagram for explaining the circuit of the magnetic coupling prevention circuit 350. According to the present embodiment, as the magnetic coupling prevention circuit 350 of the transmit RF coil, there is used a circuit which differs from the magnetic coupling prevention circuit using the parallel resonant circuit as used in the surface coil 400. This is for facilitating to fabricate the transmit RF coil. Specifically, the magnetic coupling prevention circuit 350 includes a PIN diode 330 and both ends of the PIN diode 330 are connected to a DC power supply 360 via cables 304 which are inserted with choke coils. The PIN diode 330 of the magnetic coupling prevention circuit 360 is controlled to be ON/OFF by a control current from the DC power supply 360. Thereby, when an RF signal is transmitted, the birdcage coil 300 is made to function as the transmit RF coil 103 by making the PIN diode 330 ON, and when a magnetic resonance signal is received, the birdcage coil 300 is made to have a high impedance by making the PIN diode 330 OFF to prevent the birdcage coil 300 from interfering with the receive RF coil 104 (surface coil 400).

As explained above, the receive RF coil 104 of the present embodiment has a configuration in which the loop configured by the conductor and the capacitor are connected in parallel or connected in series, and a value of the capacitor is adjusted such that a resonance frequency of the receive RF coil 104 becomes the magnetic resonance frequency f₀ which the resonance frequency of the receive RF coil 104 receives. Also, the receive RF coil 104 of the present embodiment includes the magnetic coupling prevention circuit 450. Therefore, according to the receive RF coil 104 of the present embodiment, when the RF magnetic field is transmitted, the magnetic coupling is not brought about, and the magnetic resonance signal can be received highly sensitively and with a uniform sensitivity distribution.

According to the magnetic coupling prevention circuit 450 which the receive RF coil 104 of the present embodiment includes, the magnetic coupling prevention circuit is driven by receiving the control signal by wireless communication. Therefore, the receive RF coil 104 does not need wirings with a DC power supply for driving the magnetic coupling prevention circuit 450. Therefore, a disturbance in the magnetic coupling or the sensitivity distribution by a cable is not brought about. Therefore, the sensitivity and the uniformity of the sensitivity distribution of the receive RF coil 104 can be improved.

According to the present embodiment, as the receive RF coil 104, an exclusive coil in accordance with an imaging portion and an object of imaging can be selected. For example, the surface coil 400 described above can be arranged to be brought into close contact with the test subject 130, and therefore, a magnetic resonance signal at a surrounding of a close contact portion can be detected highly sensitively.

According to the present embodiment, for example, in a case where the magnetic resonance signal which is received by the receive RF coil 104 is a magnetic resonance signal of hydrogen nucleus (magnetic resonance frequency 300 MHz) in a static magnetic field strength of 7 T (Tesla), from Equation (2), capacitances of the respective capacitors configuring the surface coil 400 may be adjusted as, for example, C_{M}=75 pF, C_{A}=0.71 pF. In this case, C_{D} becomes, for example, 3.6 pF. The value L_{C} of an inductance of the conductor 402 having the loop shape is set to 400 nH, and an impedance from the port 408 is made to be 50 Ω. Incidentally, when the test subject 130 approaches the surface coil 400, the impedance of the surface coil 400 is changed. Therefore, it is preferable to pertinently determine C_{M} and C_{A} in accordance with the test subject 130. Also, the value of the inductor 420 may be adjusted to be 78 nH since the capacitance (C_{D}) of the capacitor 411 is 3.6 pF.

Although according to the present embodiment, all of capacitance values of 4 of the capacitors 410 and the capacitor 411 are made to be 3.6 pF, the capacitances may differ. The value of the synthesized capacitance of the five capacitors is to be C_{A} (=0.71 pF).

The magnetic resonance signal received is not limited to that by hydrogen nucleus. For example, magnetic resonance signals by nuclei of fluorine (¹⁹F), carbon (¹³C), helium (³He), phosphorus (³¹P), lithium (⁷Li), xenon (¹²⁹Xe), sodium (²³N) and the like will do. Naturally, nuclei are not limited thereto. A nucleoid by which the magnetic resonance signal is generated will do.

Further, the conversion circuit 460 of the present embodiment is not limited to the configuration described above. The RF voltage may be able to be converted to the DC voltage.

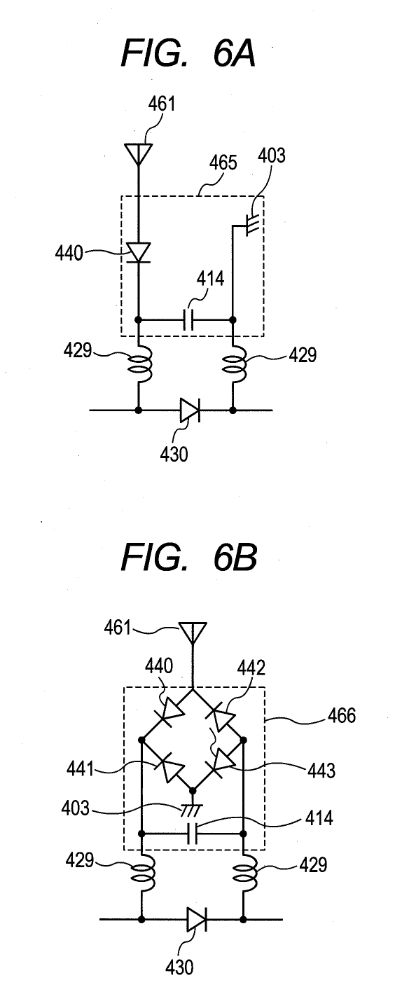

Although according to the embodiment described above, the half-wave double voltage rectifier circuit is used, for example, a half-wave rectifier circuit may be used. FIG. 6(a) shows a modified example of the conversion circuit 460 of the present embodiment and the example of using a half-wave rectifier circuit instead of the half-wave double voltage rectifier circuit (conversion circuit 465). In the drawing, the PIN diode 430 is the PIN diode which is connected in parallel with the capacitor 411 that is inserted to the conductor 402 of the surface coil 400 of the present embodiment. (The PIN diode 430 is the PIN diode 430 of the magnetic coupling prevention circuit 450.) As shown in the drawing, the half-wave rectifier circuit is configured by one of the rectifier diode 440 and one of the capacitor 414. One terminal of the rectifier diode 440 is connected to the capacitor 414 and the other terminal of the rectifier diode 440 is connected to the control signal receiving antenna 461. Incidentally, the rectifier diode 440 may be configured by plural rectifier diodes aligning polarities.

According to the half-wave rectifier circuit, an electric charge is moved only when a positive voltage is applied to the rectifier diode 440. Therefore, a voltage which is obtained by an output of the rectifier diode 440 is only a half wave of an alternating current. The obtained AC voltage is smoothed and converted into a DC voltage by the capacitor 414, thereafter, outputted to the PIN diode 430.

For example, a full wave rectifier circuit may be used for the conversion circuit 460. FIG. 6(b) shows a modified example of the conversion circuit 460 of the present embodiment and an example of using a full wave rectifier circuit instead of the half-wave double voltage rectifier circuit (conversion circuit 466). The PIN diode 430 in the drawing is the PIN diode which is connected in parallel with the capacitor 411 that is inserted to the conductor 402 of the surface coil 400 of the present embodiment. (The PIN diode 430 is the PIN diode 430 of the magnetic coupling prevention circuit 450.) As shown by the drawing, a full wave rectifier circuit which is subjected to bridge connection is configured by a group of rectifier diodes 440, 441, 442, and 443 having an input side and an output side, and the capacitor 414. The input side of the bridge connection is connected to the control signal receiving antenna 461, and the output side of the bridge connection is connected to the capacitor 414.

According to the full wave rectifier circuit, when a positive voltage is generated at the control signal receiving antenna 461, electric charges are moved to the rectifier diode 440 and the rectifier diode 443. When a negative voltage is generated at the control signal receiving antenna 461, electric charges are moved to the rectifier diode 441 and the rectifier diode 442. Therefore, a voltage which is obtained on the output side of the bridge connection is configured by a full wave. The obtained voltage is smoothed and converted into a DC voltage by the capacitor 414, thereafter, outputted to the PIN diode 430.

The half-wave rectifier circuit and the full wave rectifier circuit are rectifier circuits, and therefore, similar to the half-wave double voltage rectifier circuit, an AC voltage which is generated by the control signal receiving antenna 461 is converted into a DC voltage and is outputted. Therefore, even when any of the rectifier circuits is used for the conversion circuit 460, the PIN diode 430 of the magnetic coupling prevention circuit 450 can be made ON. Therefore, the magnetic coupling with the transmit RF coil 103 can be prevented, and the magnetic resonance signal can be received highly sensitively and with a uniform sensitivity distribution.

In a case of using the half-wave rectifier circuit, only one of the rectifier diode 440 is used. Therefore, the conversion circuit 460 can be fabricated inexpensively by a small space.

The full wave rectifier circuit converts a full wave of a radio frequency. Therefore, in a case of using the full wave rectifier circuit, the conversion circuit 460 can convert an AC voltage to a DC voltage highly efficiently, and can provide a high current to the PIN diode 430.

According to the half-wave double voltage rectifier circuit, the half-wave rectifier circuit, and the full wave rectifier circuit, voltages or currents thereof which can be outputted differ by a difference in a rectification system. Generally, the higher the output, the more increased the number of elements used and the more increased the cost. Therefore, an optimum one thereof is selected in accordance with a position of installing, an environment of using, an allowable cost of the receive RF coil 104 and so on.

An explanation has been given of the embodiment described above by taking an example of a case of using the half-wave whip antennas for the control signal transmitting antenna 471 and the control signal receiving antenna 461. However, an applicable antenna is not limited to the half-wave whip antenna. The antenna may be able to transmit and receive the control signal. For example, there may be used a micro strip antenna in which a conductor is pasted on a board of an insulator. Naturally, the antenna is not limited thereto. Although according to the present embodiment, the half-wave whip antennas are used both for the control signal transmitting antenna 471 and the control signal receiving antenna 461, it is not necessary to use the same antennas. The antennas can respectively be determined in accordance with modes of use.

An explanation has been given of the present embodiment by taking an example as the surface coil 400 of the loop shape. However, the shape of the surface coil 400 is not limited thereto.

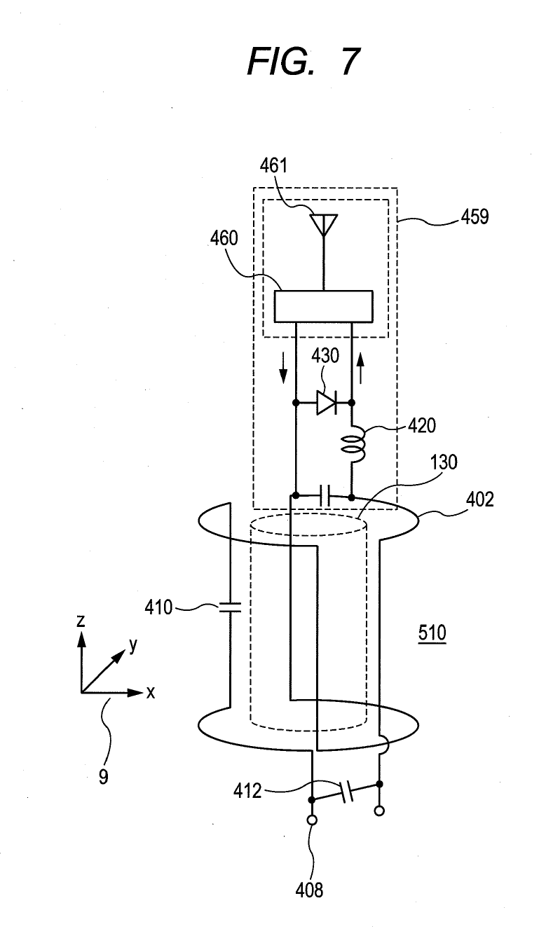

The surface coil 400 may have, for example, a shape of a saddle coil. FIG. 7 shows a surface coil (saddle coil) 510 having a saddle shape which is a modified example of the surface coil (loop coil) 400. As shown in the drawing, the saddle coil 510 has a shape in which two loops opposed to each other of the surface coil where the conductor 402 is configured in a saddle shape are connected to generate magnetic fields in the same direction, and faces of the respective loops are along a side face of a circular cylinder. Incidentally, in the drawing, the choke coil 429 is omitted.

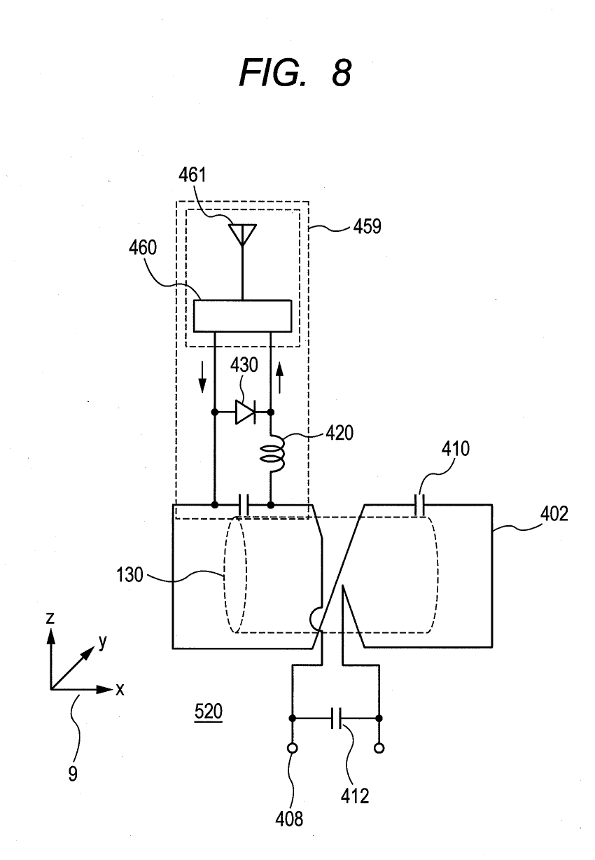

The surface coil 400 may have, for example, a shape of a butterfly coil. FIG. 8 shows a surface coil (butterfly coil) 520 having a butterfly shape which is a modified example of the surface coil (loop coil) 400 of the present embodiment. As shown in the drawing, the butterfly coil 520 has a shape in which two contiguous loops in the same plane of the surface coil where the conductor 402 is configured in a butterfly shape are connected to generate magnetic fields in directions opposed to each other. Incidentally, in the drawing, the choke coil 429 is omitted.

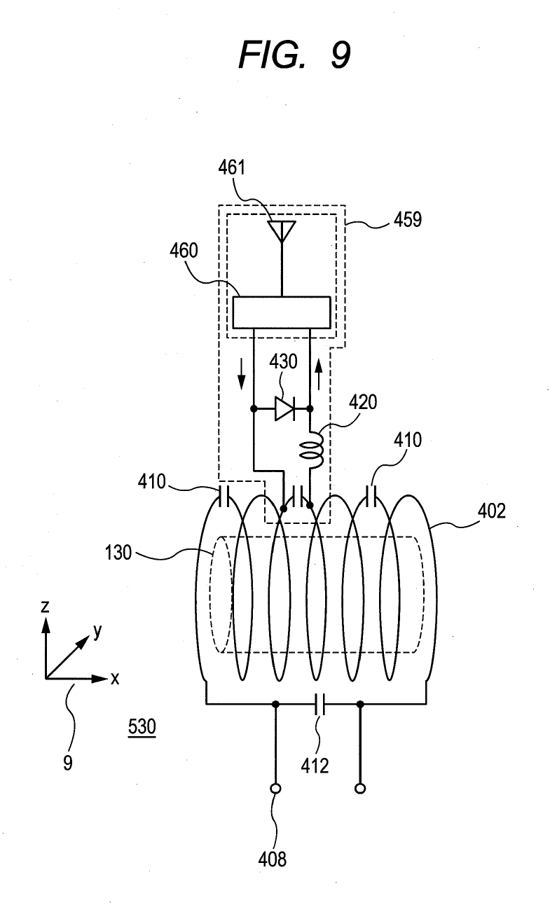

The surface coil 400 may have, for example, a solenoid shape. FIG. 9 shows a surface coil (solenoid coil) 530 having a solenoid shape which is a modified example of the surface coil (loop coil) 400 of the present embodiment. Incidentally, in the drawing, the choke coil 429 is omitted.

According to the saddle coil 510, the butterfly coil 520, and the solenoid coil 530, when the coils (conductors 402) are developed on a plane, the coils are the same as the surface coil 400 of the embodiment described above having the loop shape. Therefore, operation principles thereof are the same as that of the surface coil 400. Therefore, by using the switch circuit 459 described above, similar to the above-described, when the RF magnetic field is transmitted, the magnetic coupling with the transmit RF coil 103 is prevented, and in receiving, the magnetic resonance signal can be received highly and with a uniform sensitivity.

In a case of using the saddle coil 510 as the surface coil 400, since the saddle coil 510 has the coil in the saddle shape, the test subject 130 of the arm, the foot, or the trunk of the test subject is arranged in the saddle coil 510 as shown in FIG. 7. Thereby, the magnetic resonance signal from a region in a depth direction in addition to the surface of the test subject 130 can be detected highly sensitively and with a uniform distribution.

In a case of using the butterfly coil 520 as the surface coil 400, since the butterfly coil 520 has the coil in the butterfly shape, the test subject 130 of the arm, the foot, or the trunk of the test subject is not brought into a closed space. The magnetic resonance signal from an area in the depth direction of the test subject 130 can be detected highly sensitively and with a uniform distribution by arranging the test subject 130 at an upper portion or a lower portion of the butterfly coil 520 as shown in FIG. 8.

In a case of using the solenoid coil 530 as the surface coil 400, since the solenoid coil 530 has the coil in the solenoid shape coil. Arranging of the test subject 130 of the arm, the foot, or the trunk of the test subject in the solenoid coil as shown in FIG. 9, therefore, can detect the magnetic resonance signal from the area in the depth direction in addition to the surface of the test subject 130 highly sensitively and with a uniform distribution. Also, the solenoid coil 530 has a uniform sensitivity distribution in an area which is wider than that of the saddle type coil 510.

In the embodiment as well as the saddle coil 510, the butterfly coil 520, and the solenoid coil 530 which are the modified examples of the embodiment, there are exemplified cases of installing the respective single magnetic coupling prevention circuits 450. However, the plural magnetic coupling prevention circuits 450 may be included.

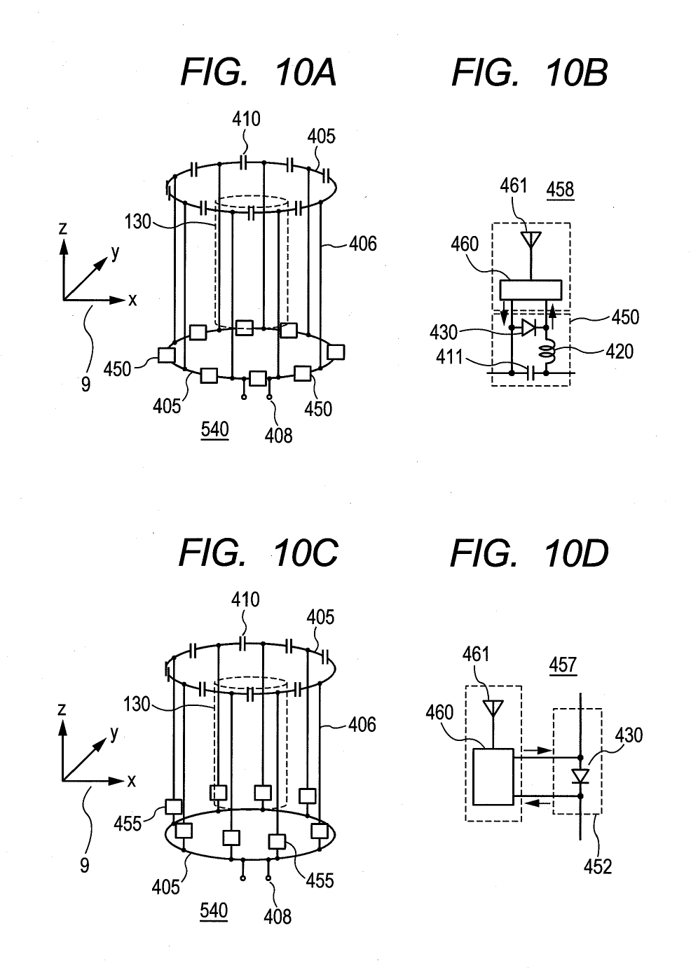

The surface coil 400 may have, for example, a birdcage shape. FIG. 10(a) shows a surface coil (birdcage coil) 540 having a birdcage shape which is a modified example of the surface coil (loop coil) 400 of the present embodiment. As shown in the drawing, the birdcage coil 540 has a birdcage shape in which two of loop conductors 405 are connected by plural linear conductors 406. In a case where the surface coil 400 is the birdcage coil 540, as shown in FIG. 10(a), the magnetic coupling prevention circuits 450 are inserted among connection points with the respective linear conductors 406 of the loop conductor 405 which is connected to the receiver 114 via the port 408.

FIG. 10(b) shows a switch circuit 458 of the modified example. Incidentally, in the drawing, the choke coil 429 is omitted. According to the birdcage coil 540, although a shape of the conductor (405, 406) differs, the configuration of the switch circuit configured by the control signal receiving antenna 461, the conversion circuit 460, and the magnetic coupling prevention circuit 450 stays the same. Therefore, the operation principle for preventing the magnetic coupling with the surface coil 400 stays the same.

Therefore, by using the switch circuit 458, similar to the above-described, when the RF magnetic field is transmitted, the magnetic coupling with the transmit RF coil 103 is prevented, and in receiving, the magnetic resonance signal can be received highly and with a uniform sensitivity.

The birdcage coil 540 has the coil configured by the birdcage coil. Therefore, as shown in FIG. 10(a), by arranging the test subject 130 of the arm, the foot, the trunk or the like of the test subject in the birdcage shape, the magnetic resonance signal from an area in the depth direction in addition to the surface of the test subject 130 can be detected highly sensitively and with a uniform distribution. Also, the birdcage coil 540 has a uniform sensitivity distribution in an area which is wider than that of the saddle coil 510.

Incidentally, in the respective modified examples, a number of the capacitors 410 which are installed to the conductor 402 (or conductor 405) is not limited.

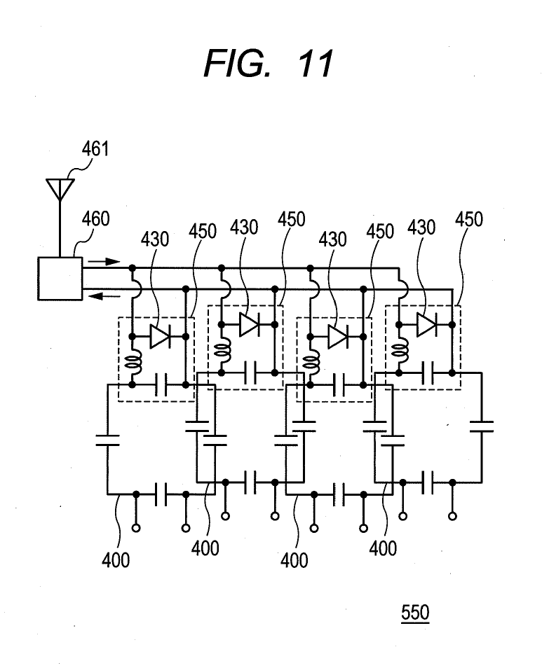

As the receive RF coil 104, there can also be used an array coil 550 shown in FIG. 11. The array coil 550 is configured by plural (4 pieces in FIG. 11) surface coils (loop coils) 400 in a loop shape which are partially overlapped with each other. At a position of overlapping the contiguous loop coils 400, it is adjusted that the magnetic coupling is not brought about at the respective loop coils 400. The respective loop coils 400 include the magnetic coupling prevention circuits 450. The PIN diode 330 of the magnetic coupling prevention circuit 450 is connected to the conversion circuit 460. Incidentally, in the drawing, the choke coil 420 is omitted.

The PIN diode 430 of the magnetic coupling prevention circuit 450 is driven by receiving the control signal similar to the embodiments described above. At this occasion, as shown in FIG. 11, the PIN diodes 430 of the plural magnetic coupling prevention circuits 450 may be configured to be driven by a voltage provided by the single control signal receiving antenna 461 and the single conversion circuit 460. Also, each surface coil 400 may be configured to include the switch circuit 459 configured by the control signal receiving antenna 461, the conversion circuit 460, and the magnetic coupling prevention circuit 450.

Imaging can be carried out by using the array coil 550 over an area which is wider than that in the case of using one piece of the surface coil 400. Therefore, for example, in an area over a total of the trunk of the test subject (patient) which is the test subject 130, the magnetic resonance signals can be received with a high sensitivity and simultaneously.

In the case of using the array coil 550 as the receive RF coil 104, it may be configured that control signals having plural different frequencies are transmitted. In this case, for example, the magnetic coupling prevention circuits 450 of the individual coils are individually driven by attaching the control signal receiving antennas 461 and the conversion circuits 460 having different frequency characteristic for respective loop coils configuring the array coil 550 and changing the frequencies of the control signals transmitted.

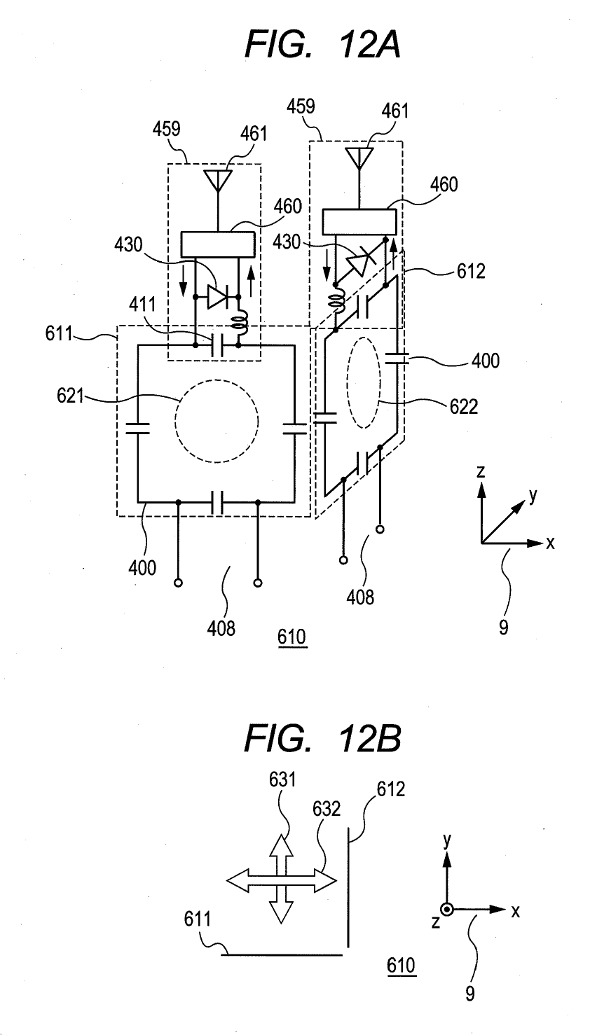

As the receive RF coil 104, there may be used a QD coil 610 of a (QD: Quadrature Detection) system shown in FIG. 12. The QD coil 610 is a coil combining two of the surface coils 400 in the loop shape and improving an irradiation efficiency and a receiving sensitivity of the RF coil.

FIG. 12(a) is a circuit diagram of the QD coil 610. As shown in the drawing, the QD coil 610 of a modified example of the present embodiment includes a first surface coil 611 and a second surface coil 612.

The first surface coil 611 and the second surface coil 612 are respectively connected with the switch circuits 459. The PIN diode 430 which the switch circuit 459 includes is driven by the control signal which is received by way of the control signal receiving antenna 461 and the conversion circuit 460 and the first surface coil 611 and the second surface coil 612 are made to have high impedances similar to the present embodiment.

Incidentally, the respective switch circuits 459 of the first surface coil 611 and the second surface coil 612 may serve also as the control signal receiving antennas 461 and the conversion circuits 460 similar to the case of the array coil 550 shown in FIG. 11.

The configurations of the respective surface coils 611 and 612 are similar to the surface coil 400 of the present embodiment. For example, the first surface coil 611 and the second surface coil 612 are respectively adjusted to respective magnetic resonance frequencies of the hydrogen nucleus.

However, the first surface coil 611 and the second surface coil 612 of the QD coil 610 are arranged such that loop faces of the first surface coil 611 and the second surface coil 612 (first loop face 621, second loop face 622) are in parallel with z-axis. Also, the second surface coil 612 is arranged at a position of rotating the first surface coil 611 by 90 degrees with z-axis as a rotating axis.

FIG. 12(b) is a diagram viewing the QD coil from a direction in which a static magnetic field penetrates (z-axis direction in the drawing). As shown in the drawing, in the QD coil 610 of the present embodiment, a direction 631 of a magnetic field which is generated by the first surface coil 611 and a direction 632 of a magnetic field which is generated by the second surface coil 612 are orthogonal to each other. Therefore, the first surface coil 611 and the second surface coil 612 are not magnetically coupled but are operated as RF coils for the magnetic resonance signals respectively independently.

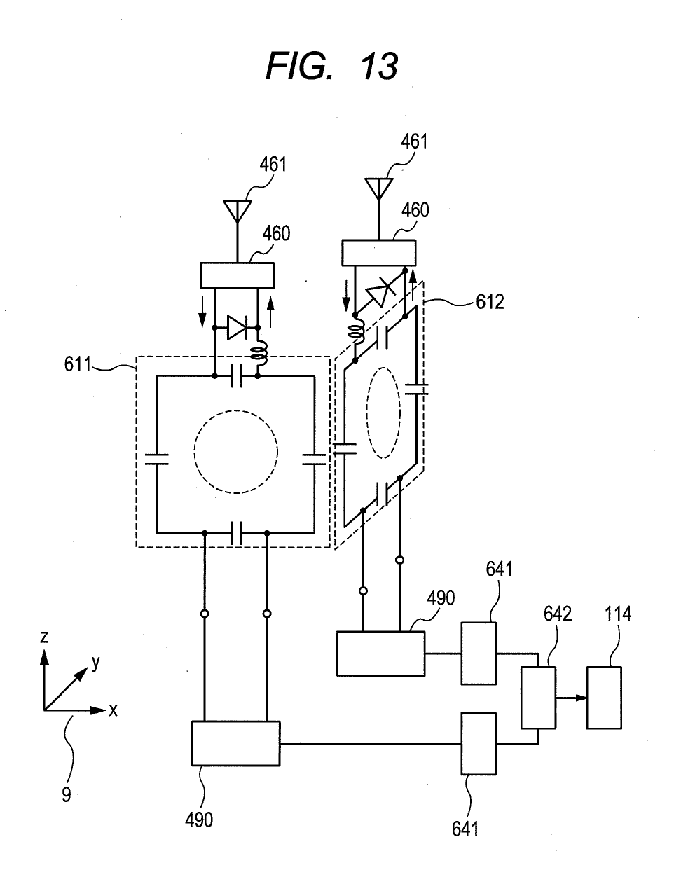

FIG. 13 is a block diagram for explaining connection of the first surface coil 611 and the second surface coil 612 of the QD coil 610, phase shifters 641, a synthesizer 642, and the receiver 114. Outputs from the two surface coils 611 and 612 are respectively inputted to the phase shifters 641 by passing the signal processing circuits 490. Signals phases of which have been adjusted by the phase shifters 641 are inputted to and synthesized by the synthesizer 642. The signal as synthesized is inputted to the receiver 114.

As described above, the first surface coil 611 and the second surface coil 612 are respectively adjusted to resonate at the respective resonance frequencies of the hydrogen nucleus. Therefore, the first surface coil 611 and the second surface coil 612 detect signal components which are respectively orthogonal to each other for the magnetic resonance signals of the hydrogen nucleus which are generated from the test subject 130. The respective detected signal components are respectively amplified by the signal processing circuits 490, respectively processed by the phase shifters 641, thereafter, synthesized by the 642 and sent to the receiver 114. As described above, the QD coil 610 realizes the QD style reception.

As explained above, in the case of using the QD coil 610 as the receive RF coil 104, the reception by the QD style is realized. Therefore, the magnetic resonance signals can be detected with a higher sensitivity in addition to the effect that is achieved in the case of using the surface coil 400 in the loop shape.

Here, the explanation has been given by taking an example of combining two of the surface coils 400 of the first embodiment in order to realize the reception by the QD type. However, the applicable RF coil is not limited thereto. Magnetic fields respectively generated by two coils may be able to be configured to be orthogonal to each other. For example, the QD coil 610 may be configured by arranging two of the saddle coils by shifting the saddle coils by 90 degrees with z-axis as the rotating axis. Also, the QD coil 610 may be configured by arranging the solenoid coil and the saddle coil such that directions of circular cylinders thereof are the same as each other.

According to the present embodiment, the surface coil 400 is configured to have a high impedance when the control signal is received. However, switching means of the circuit configuration of the surface coil 400 is not limited thereto. Conversely, the surface coil 400 may be configured to have a high impedance when the control signal is not received.

FIG. 110(d) shows a switch circuit 457 in this case. The switch circuit 457 includes the control signal receiving antenna 461, the conversion circuit 460, and a magnetic coupling prevention circuit 452. The PIN diode 430 of the magnetic coupling prevention circuit 452 is connected in series with the conductor 460 of the RF coil. The PIN diode 430 is driven by a DC voltage which is received by way of the control signal receiving antenna 461 and the conversion circuit 460. That is, the switch circuit 457 is made ON when the control signal is received, and is made OFF in a state of not receiving the control signal.

The magnetic coupling prevention circuits 452 are inserted to the respective linear conductors 406 of the birdcage coil 540 as shown in FIG. 10(c), for example, in a case of using the birdcage coil 540 for the surface coil 400. When the control signal is received, the PIN diode 430 is made ON to make the birdcage coil 540 function as the receive RF coil 104. In the state where the control signal is not received, the PIN diode 430 is made OFF, the birdcage coil 540 is made to have a high impedance, and does not interfere with the transmit RF coil 103.

In the case of using the switch circuit 457, in the imaging sequence shown in FIG. 3(b), the control (CS) is controlled to be transmitted when the magnetic resonance signal is received, and not to be transmitted when the radio frequency signal by the transmit RF coil 103 is transmitted.

The switch circuits 457, 458, and 459 of the present embodiment may be applied to the transmit RF coil 103. For example, the switch circuit 457 is applied to the transmit RF coil 103, and the switch circuit 459 or the switch circuit 458 is applied to the receive RF coil. The control signal (CS) is controlled to be transmitted when the radio frequency magnetic field is transmitted. By configuring in this way, when the high frequency magnetic field is transmitted, the PIN diode 430 of the switch circuit 457 of the transmit RF coil 103 is made ON, the transmit RF coil is made to function, the PIN diode 430 of the switch circuit 459 of the receive RF coil 104 is made OFF, and the receive RF coil 104 is made to have a high impedance. When the magnetic resonance signal is received, the PIN diode of the switch circuit 457 of the receive RF coil 104 is made ON, the receive RF coil is made to function, the PIN diode 430 of the switch circuit 457 of the transmit RF coil 103 is made OFF, and the transmit RF coil 103 is made to have a high impedance.

When configured in this way, either of the transmit RF coil 103 and the receive RF coil 104 can change the circuit configuration by the control signal by wireless. Incidentally, in this case, the control signal receiving antenna 461 and the conversion circuit 460 may commonly be shared by the switch circuit 459 and the switch circuit 457.

### Second Embodiment

Next, an explanation will be given of a second embodiment to which the present invention is applied. According to the embodiment, in an MRI device separately including a transmit RF coil and a receive RF coil, a switch circuit which changes a circuit configuration of the receive RF coil by a control signal transmitted by wireless is used not only as a magnetic coupling prevention circuit, but is used as a frequency changing circuit of changing a resonance frequency of the receive RF coil. The MRI device of the present embodiment is basically similar to that of the first embodiment. An explanation will be given as follows of a configuration which differs from that of the first embodiment as the main point.

Also in the present embodiment, similar to the first embodiment, an explanation will be given by taking an example of a case of a transmit and receive type in which a birdcage coil 301 having a birdcage shape is used for the transmit RF coil 103, and a surface coil 401 having a loop shape is used for the receive RF coil 104. Also resonance frequencies of the receive RF coil 104 which are changed by control signals are respectively made to be a first resonance frequency f₁ and a second resonance frequency f₂. In accordance therewith, the birdcage coil 301 of the embodiment is made to be adjusted to be able to transmit RF signals having the two kinds of resonance frequencies (double tuning birdcage coil). Incidentally, an explanation will be given as follows by setting the first resonance frequency f₁ smaller than the second resonance frequency f₂ (f₁<f₂).

First, an explanation will be given of a configuration of an RF coil portion 501, an RF magnetic field, a gradient magnetic field, and timings of generating control signals according to the present embodiment.

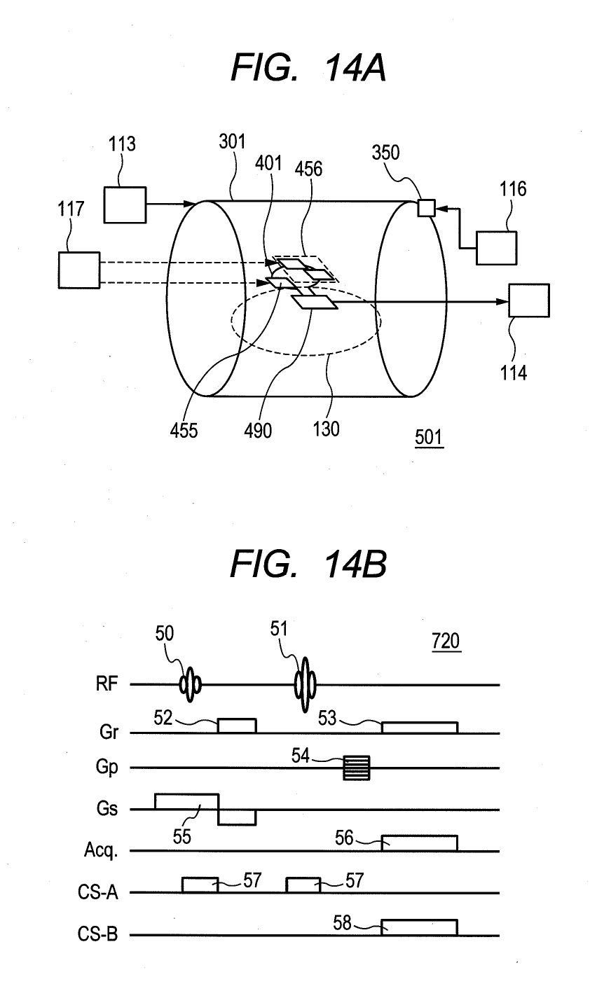

FIG. 14(a) is a block diagram for explaining connection of the RF coil portion 501 according to the present embodiment. As shown in the drawing, the birdcage coil 301 which is used as the transmit RF coil 103 of the present embodiment transmits an RF magnetic field which is generated by the RF magnetic field generator 113. The birdcage coil 301 is inserted with the magnetic coupling prevention circuit 350. Similar to the first embodiment, the magnetic coupling prevention circuit 350 is connected to the DC Power Supply, and is driven by the DC Power Supply.

A switch circuit 456 and a switch circuit 455 are inserted to the loop coil (surface coil) 401 which is used as the receive RF coil 104. The switch circuit 456 and the switch circuit 455 are driven by control signals which are transmitted from the control signal transmitter 117 by wireless. A magnetic resonance signal which is received by a surface coil 401 is transmitted to the receiver 114 via the signal processing circuit 490 including a balun or a pre amplifier.

The switch circuit 456 and the switch circuit 455 of the present embodiment are individually controlled by control signals having respectively different frequencies. Although the configuration of the control signal transmitter 117 is similar to that of the first embodiment, the control signal transmitter 117 is adjusted to be able to transmit control signals of two frequencies.

The switch circuit 456 is inserted to the conductor of the surface coil 401. The switch circuit 456 is driven by the control signal which is transmitted from the control signal transmitter 117 by wireless, changes the circuit configuration of the surface coil 401, brings the surface coil 400 into an open state, and prevents the magnetic coupling with the transmit RF coil 103.

The switch circuit 455 is inserted to the conductor of the surface coil 401. The switch circuit 455 is driven by the control signal from the control signal transmitter 117, changes the circuit configuration of the surface coil 401, and changes the resonance frequency of the surface coil 401.

FIG. 14(b) shows timings of transmitting a first control signal (CS-A) which drives the switch circuit 456 and a second control signal (CS-B) which drives the switch circuit 455. FIG. 14(b) is a timing chart of an SE (Spin Echo) method which is one of imaging methods of MRI. The timing of transmitting the control signal by the control signal transmitter 117 will be shown in reference to the drawings. Notation ‘RF’ designates a timing of transmitting a radio frequency by the transmit RF coil 103. Notations ‘Gr’, ‘Gp’, and ‘Gs’ designate timings of generating the gradient magnetic fields by the gradient coil 102. Notation ‘Acq.’ designates a timing of carrying out data acquisition by the receive RF coil 104. Notation ‘CS-A’ designates a timing of the first control signal which drives the switch circuit 456 by the control signal transmitter 117 in a case of preventing magnetic coupling. Notation ‘CS-B’ designates a timing of the second control signal which drives the switch circuit 455 by the control signal transmitter 117 in a case of acquiring the second resonance frequency f₂. A specific explanation will be given as follows.

At first, an explanation will be given of the imaging method of the SE method. First, the 90° pulse 50 is transmitted while applying the slice selective magnetic field 55. Thereafter, the dephase magnetic field 52 is applied. Next, the 180° pulse 51 is transmitted. Thereafter, the encode magnetic field 54 is applied. Finally, the lead-out magnetic field 53 is applied, and a generated magnetic resonance signal is subjected to the data acquisition 56. The above-described is the timing chart of the SE method. Under such timings, the control signal 67 (first control signal: CS-A) to the switch circuit 456 is transmitted when the 90° pulse 50 is transmitted and when the 180° pulse 51 is transmitted. Also, a control signal 58 (second control signal: CS-B) to the switch circuit 455 is transmitted when data is acquired (received) in a case of acquiring a signal of the second resonance frequency. However, in a case where the first resonance frequency f₁ is acquired, the control signal (second control signal: CS-B) to the switch circuit 455 is not outputted.

Incidentally, the timings of transmitting the control signals (CS) are not limited to the above-described. The transmission of the control signal (first control signal) to the switch circuit 456 may be of any timing waveform so far as the control signal (first control signal) is transmitted when the high frequency signal RF is transmitted (ON state), and is not transmitted in receiving (OFF state). Also, the transmission of the control signal to the switch circuit 456 (second control signal) may be of any timing waveform so far as the control signal (second control signal) is transmitted in receiving the signal of the second resonance frequency at minimum in a case of acquiring the second resonance frequency f₂.

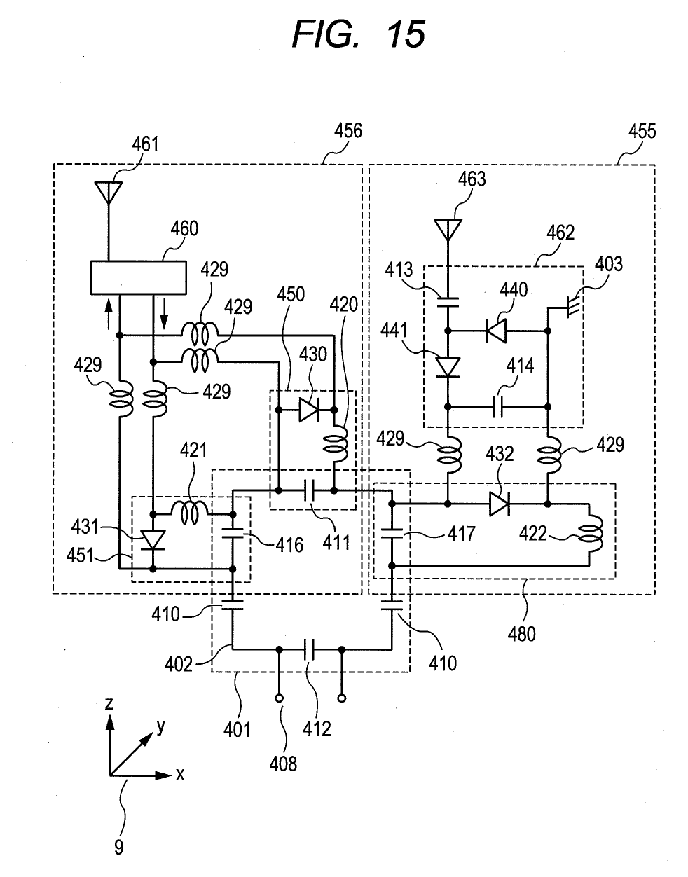

Next, an explanation will be given of configurations of the surface coil 401, the switch circuit 456, and the switch circuit 455 according to the present embodiment in reference to FIG. 15.

The surface coil 401 is configured basically similar to that of the first embodiment. The surface coil 401 is of a parallel resonant circuit in which the matching capacitor 412 having the capacitance of C_{M} is connected in parallel with the series resonant circuit in which the plural capacitors 410 having the capacitance of C_{D}, the capacitor 411 having the capacitance of C_{D}, and the capacitor 416 having the capacitance of C_{D} are inserted to the conductor 402 having the loop shape at equal intervals. The conductor 402 having the loop shape is connected to the signal processing circuit 490 via the port 408.

However, capacitances of the capacitors 410, 411, 416, 417, and 412 of the surface coil 401 of the present embodiment are adjusted such that the surface coil 401 is resonated at the first resonance frequency f₁.

The switch circuit 456 includes the magnetic coupling prevention circuit 450 which is adjusted to be able to prevent the magnetic coupling of the surface coil 401 at the first resonance frequency f₁, a magnetic coupling prevention circuit 451 which is adjusted to be able to prevent the magnetic coupling at the second resonance frequency f₂, the conversion circuit 460 which is connected to the two magnetic coupling prevention circuits 450 and 451, and the control signal receiving antenna 461 which is connected to the conversion circuit 460 and which receives the first control signal.

The magnetic coupling prevention circuit 450 is a circuit in which the capacitor 411 of the surface coil 400 is connected in parallel with a series circuit of the inductor 420 and the PIN diode 430. The inductor 420 and the capacitor 411 are adjusted to resonate in parallel at the first resonance frequency f₁. Also, the magnetic coupling prevention circuit 451 is a circuit in which the capacitor 416 of the surface coil 400 is connected in parallel with a series circuit of an inductor 421 and a PIN diode 431. The inductor 421 and the capacitor 416 are adjusted to be resonated in parallel at the second resonance frequency f₂.

Operations of the magnetic coupling prevention circuit 450 and the magnetic coupling prevention circuit 451 when the control signal is received and when the control signal is not received are similar to those of the first embodiment. Respectively when a radio frequency signal having the first resonance frequency f₁ is transmitted and when a radio frequency signal having the second resonance frequency f₂ is transmitted, the PIN diode 430 and the PIN diode 431 are respectively made ON to make the surface coil 400 have a high impedance to prevent the surface coil 400 from interfering with the transmit RF coil 103 (birdcage coil 301).

The conversion circuit 460 and the control signal receiving antenna 461 are configured similar to those of the first embodiment. Also, similar to the first embodiment, the choke coils 429 are connected respectively to the both ends of the PIN diodes 430 and 431 and connected to the magnetic coupling prevention circuit 450 and the magnetic coupling prevention circuit 451.

Incidentally, although here, as an example, the explanation has been given by taking an example of a case where the single conversion circuit 460 is connected to the magnetic coupling prevention circuit 450 and the magnetic coupling prevention circuit 451. The magnetic coupling prevention circuit 450 and the magnetic coupling prevention circuit 451 may be configured to be connected to the conversion circuits 460 and the control signal receiving antennas 461 separately independently from each other.

The switch circuit 455 includes a frequency changing circuit 480 which changes the resonance signal of the surface coil 401 by the control signal, a conversion circuit 462 which is connected to the frequency changing circuit 480, and a control signal receiving antenna 463 which is connected to the conversion circuit 462 and which receives the second control signal.

The frequency changing circuit 480 is a circuit in which the capacitor 417 of the surface coil 400 is connected in parallel with a series circuit of an inductor 422 and a PIN diode 432. The frequency changing circuit 480 is a parallel resonant circuit which is configured by the inductor 422 and the capacitor 417, and a resonance frequency f_{S} thereof is adjusted to have a frequency lower than the second resonance frequency (f_{S}<f₂). Values of the inductor 422 and the capacitor 417 are adjusted such that the surface coil 401 is resonated at the second resonance frequency f₂ when a current flows in the PIN diode 432.

Although the conversion circuit 462 and the control signal receiving antenna 463 are configured similar to the conversion circuit 460 and the control signal receiving antenna 461 of the first embodiment, the control signal receiving antenna 463 is adjusted to be tuned with a frequency which is different from the frequency of the first control signal. Similar to the conversion circuit 460 of the first embodiment, the conversion circuit 462 is connected to the frequency changing circuit 480 via the choke coils 429 which are connected to both ends of the PIN diode 432.

An explanation will be given here of the principle of resonating the surface coil 401 which is adjusted to resonate at the first resonance frequency f₁, at the second resonance frequency f₂ by the frequency changing circuit 480.

Generally, a parallel resonant circuit is operated as an inductive reactance when a frequency which is lower than a resonance frequency of the parallel resonant circuit is applied to the parallel resonant circuit, and is operated as a capacitive reactance when a frequency higher than the resonance frequency is applied thereto. Therefore, the frequency changing circuit 480 which is a parallel resonant circuit a resonance frequency of which is adjusted to f_{S} is operated as a capacitive reactance when a signal having the second resonance frequency f₂ which is a frequency higher than the resonance f_{S} is applied thereto. The frequency changing circuit 480 at this occasion is operated as in a capacitor, and a value C′ of the capacitor is represented by Equation (3) as follows when a value of the capacitor 417 is designated by notation C_{B}.

C′=C_{S}(1−f_{S}²/f₂²) (3)

That is, when a current flows in the PIN diode 432 and the PIN diode 432 is made ON, the capacitor 417 which configures the surface coil 401 is operated as a capacitor configured by the capacitor 417 and the inductor 422. At this occasion, also a value of the capacitor is changed from C_{B} to C′, and therefore, the resonance frequency of the surface coil is changed.

Therefore, when the value of the capacitor 417 is C′ which is obtained by Equation (3), if values of the capacitor 417 and the inductor 422 are determined such that the surface coil 401 is resonated at the second resonance frequency f₂, the resonance frequency of the surface coil 401 is changed from the first resonance frequency f₁ to the second resonance frequency f₂ by the frequency changing circuit 480.

For example, the first resonance frequency f₁ is made to be 282 MHz which is a magnetic resonance frequency of a magnetic resonance signal of the fluorine nucleus at a static magnetic field strength of 7 T (Tesla) and the second resonance frequency f₂ is made to be 300 MHz which is a magnetic resonance frequency of a magnetic resonance signal of the hydrogen nucleus. In this case, the surface coil 401 is adjusted to resonate at 282 MHz which is the magnetic resonance frequency of the magnetic resonance signal of the fluorine nucleus in a state where the control signal is not received. At this occasion, values of the respective capacitors are adjusted such that a value (C_{M}) of the capacitor 412 is 80 pF, a value (C_{D}) of other capacitors 410, 411, 416, or 417 is adjusted to 4.0 pF by Equation (1).

In a case where a current flows in the PIN diodes 432 and a value of the capacitor 417 is changed by receiving the control signal, in order to resonate the surface coil 401 at 300 MHz which is the magnetic resonance frequency of the magnetic resonance signal of the hydrogen nucleus, the value (L_{A}) of the inductor 422 may be adjusted to 183 nH from Equation (1) and Equation (3).

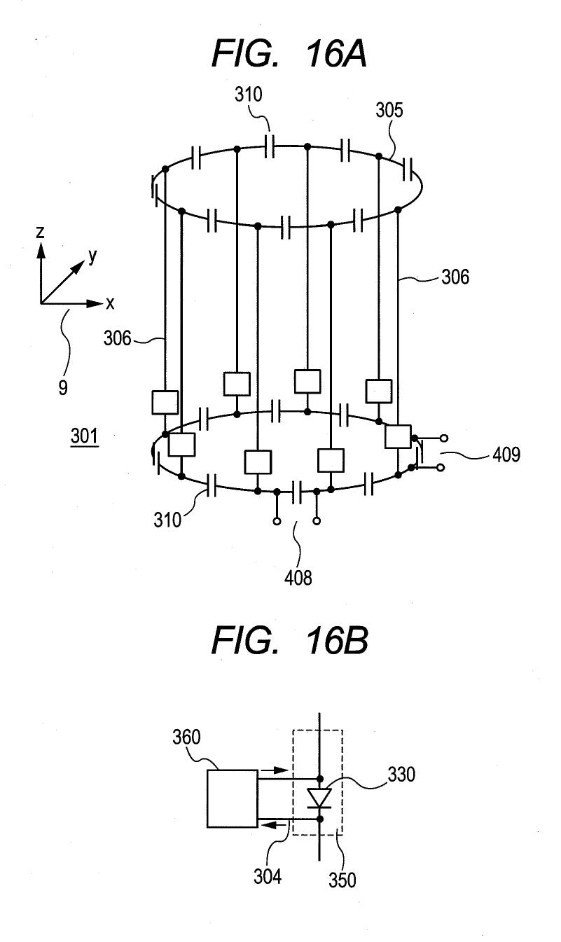

Next, an explanation will be given of a birdcage coil 301 which is used as the transmit RF coil 103 of the present embodiment in reference to FIG. 16. The birdcage coil 301 of the present embodiment is configured basically similar to that of the first embodiment. However, the birdcage coil 301 is configured to be able to transmit radio frequencies of two frequencies of the first resonance frequency and the second resonance frequency.

Specifically, as shown in FIG. 16(a), a second port 409 is arranged at a position of rotating the birdcage coil 301 by 90 degrees with z-axis as a rotating axis in addition to the port 408 of the birdcage coil of the first embodiment. At this occasion, the value of the capacitor 310 is adjusted such that the birdcage coil 301 in view from the port 408 is resonated at the first resonance frequency, and the birdcage coil 301 in view from the port 409 is resonated at the second resonance frequency. The birdcage coil 301 is connected to the RF magnetic field generator 113 respectively via the ports 408 and 409.

FIG. 16(b) is a diagram for explaining the circuit of the magnetic coupling prevention circuit 350 of the present embodiment. The magnetic coupling prevention circuit 350 of the present embodiment also includes the PIN diode 330 similar to the first embodiment. The PIN diode 330 is driven by the control current from the DC power supply 360 which is connected to the both ends of the PIN diode 330 via the cable 304 which inserts the choke coils to both ends thereof to prevent the magnetic coupling with the receive RF coil 104. The operation principle is similar to that of the first embodiment.

As has been explained above, according to the present embodiment, the resonance frequency of the surface coil 401 can be changed from the first resonance frequency to the second resonance frequency by the switch circuit 455 which is driven by the control signal that is transmitted by wireless.

In a case where the surface coil 401 which is adjusted to resonate at the first resonance frequency is used as the receive RF coil 104 which is resonated at the second resonance frequency, if the second control signal is transmitted at a timing by which the second magnetic resonance signal is intended to acquire as shown in FIG. 14(b), the control signal is converted into a DC voltage by the conversion circuit 462, and the PIN diode 431 of the frequency changing circuit 480 is made ON. Therefore, the resonance frequency of the surface coil 401 is changed from the first resonance frequency to the second resonance frequency.

As has been explained above, the receive RF coil 104 of the present embodiment includes the frequency changing circuit 480, and two kinds of desired resonance frequencies can be realized by adjusting the values of the inductor 422 and the capacitor 417. The frequency changing circuit 480 is driven by receiving the control signal by the wireless communication. Therefore, wirings with the DC power supply are not needed for driving the frequency changing circuit 480. Therefore, there is not magnetic coupling or a disturbance in a sensitivity distribution by a cable. Therefore, two kinds of resonance frequencies can be realized highly sensitively without deteriorating the uniformity of the sensitivity distribution of the receive RF coil 104.

According to the receive RF coil 104 of the present embodiment, also the magnetic coupling prevention circuit is driven by the wireless communication. Therefore, similar to the first embodiment, there is not magnetic coupling or a deterioration in the sensitivity distribution by a cable. The magnetic coupling can effectively be avoided, and the magnetic resonance signal can be received highly sensitively and with a uniform sensitivity distribution.

Although according to the present embodiment, the second resonance frequency f₂ which is realized by transmitting the control signal is made to be a frequency which is higher than the first resonance frequency f₁, the second resonance frequency f₂ may be lower than the first resonance frequency f₁. In this case, for example, the resonance frequency f_{S} of the parallel resonant circuit of the inductor (L_{A}) 422 and the capacitor (C_{A}) 417 of the present embodiment is made to be higher than the second resonance frequency. Or, the inductor 422 is changed to a capacitor, and a value of the capacitor is adjusted such that the resonance frequency of the surface coil 401 is made to be the second resonance frequency f₂ which is lower than the resonance frequency of the surface coil when the PIN diode 432 is made ON.

Although according to the present embodiment, the control signal is transmitted from the control signal transmitter 117 which is configured by the control signal generator 370 and the control signal transmitting antenna 471, the present embodiment is not limited thereto. As described above, according to the present embodiment, the birdcage coil 301 is configured to be able to transmit the RF magnetic field having the first resonance frequency f₁ and the RF magnetic field having the second resonance frequency f₂. It may be configured by using the fact such that, for example, the frequency of the second control signal is made to be the first resonance frequency f₁, the second control signal is generated by the RF magnetic field generator 113, and the second control signal is transmitted from the birdcage coil 301.

In this case, the tuning frequency of the control signal receiving antenna 463 which receives the second control signal of the surface coil 401 of the present embodiment is adjusted to the resonance frequency f₁. Further, in a case where the magnetic resonance signal of the first resonance frequency f₁ is acquired, the second control signal is not outputted from the birdcage coil 301. In a case where the magnetic resonance signal of the second resonance frequency f₂ is acquired, the second control signal is transmitted from the birdcage coil 301 to make the PIN diode 432 ON. Thereby, the resonance frequency of the surface coil 301 is made to be the first resonance frequency (resonance frequency of fluorine nucleus) in a case where the magnetic resonance signal of the first resonance frequency f₁ is acquired. The magnetic resonance signal of the first resonance frequency f₁ can be received. Also, in a case where the magnetic resonance signal of the second resonance frequency f₂ is acquired, the resonance signal of the surface coil 401 becomes the second resonance frequency (resonance frequency of hydrogen nucleus), and the magnetic resonance signal of the second resonance frequency f₂ can be received.

By substituting the control signal transmitter 117 for the RF magnetic field generator 113 and the birdcage coil 301, the control signal transmitter 117 can be omitted. Therefore, the configuration of the device can be simplified.

Although according to the present embodiment, the tuning frequency of the control signal receiving antenna 463 which receives the second control signal is made to be the first resonance frequency f₁, the tuning frequency may not completely coincide with the first resonance frequency f₁. For example, the tuning frequency may be a frequency which is lower than the first resonance frequency f₁ by about 10 through 20%, or a frequency which is higher than the first resonance frequency f₁ by about 10 through 20%.

The transmit RF coil 103 of the present embodiment is not limited to the double tuning birdcage coil 301. For example, the transmit RF coil 103 may be a double tuning surface coil, a double tuning saddle coil, a double turning butterfly coil, or a double tuning solenoid coil. Naturally, the transmit RF coil 103 is not limited thereto. The transmit RF coil 103 may be an RF coil which can transmit two or more of frequencies.

According to the present embodiment, the explanation has been given by taking an example of the case where the combination of the first resonance frequency and the second resonance frequency is made to be a combination of the magnetic resonance frequency of the fluorine nucleus and the magnetic resonance frequency of the hydrogen nucleus. However, the combination is not limited thereto. For example, the combination may be a combination of hydrogen and helium (³He), hydrogen and phosphorus (³¹P), hydrogen and lithium (⁷Li), hydrogen and xenon (¹²⁹Xe)hydrogen and sodium (²³N), hydrogen and carbon (¹³C), hydrogen and oxygen (¹⁹O) or the like. Naturally, the combination of nuclei is not limited thereto.

Magnetic coupling prevention circuits which are driven by a DC power supply of a conventional type may be used for the magnetic coupling prevention circuits 450 and 451 of the receive RF coil of the present embodiment.

According to the present embodiment, only the frequency changing circuit 480 may be applied to a transmit and receive RF coil.

Although in the respective embodiments described above, the explanation has been given by taking an example of a case where the switch circuit which has the above-described configuration and which is driven by the control signal that is transmitted by wireless is used as the magnetic coupling prevention circuit and/or the frequency changing circuit, a circuit of applying the switch circuit is not limited thereto. The switch circuit can be used in various kinds of circuits which change circuit configurations by the control signal.

Although according to the respective embodiments described above, the explanation has been given by taking an example of the PIN diode as the switching means which is subjected to ON/OFF control by the control signal within the switch circuit, the switching means is not limited thereto. For example, the switching means maybe an element or a circuit which changes the circuit configuration of the RF coil by an electric signal as a relay or a transistor.

### LIST OF REFERENCE SIGNS

9: coordinate axis, 50: 90° pulse, 51: 180° pulse, 52: dephase magnetic field, 53: rephase magnetic field, 54: encode magnetic field, 55: slice selective magnetic field, 56: data acquisition, 57: control signal, 58: control signal, 100: MRI device, 101: vertical magnetic field type magnet, 102: gradient coil, 103: transmit RF coil, 104: receive RF coil, 105: shim coil, 110: computer, 111: sequencer, 112: gradient magnetic field power supply, 113: RF magnetic field generator, 114: receiver, 115: shim power supply, 116: DC power supply, 117: control signal transmitter, 120: table, 121: display, 122: storage medium, 130: test subject, 200: MRI device, 201: horizontal magnetic field type magnet, 300: birdcage coil, 301: birdcage coil, 304: cable, 305: loop conductor, 306: linear conductor, 310: capacitor, 330: PIN diode, 350: magnetic coupling prevention circuit, 360: DC power supply, 400: surface coil, 401: surface coil, 402: conductor, 403: the ground, 405: loop conductor, 406: linear conductor, 408: port, 410: capacitor, 411: capacitor, 412: capacitor, 413: capacitor, 414: capacitor, 416: capacitor, 417: capacitor, 420: inductor, 421: inductor, 422: inductor, 429: choke coil, 430: PIN diode, 431: PIN diode, 432: PIN diode, 440: rectifier diode, 441: rectifier diode, 442: rectifier diode, 443: rectifier diode, 450: magnetic coupling prevention circuit, 451: magnetic coupling prevention circuit, 452: magnetic coupling prevention circuit, 455: switch circuit, 456: switch circuit, 457: switch circuit, 458: switch circuit, 459: switch circuit, 460: conversion circuit, 461: control signal receiving antenna, 462: conversion circuit, 463: control signal receiving antenna, 465: conversion circuit, 466: conversion circuit, 470: control signal generator, 471: control signal transmitting antenna, 480: frequency changing circuit, 490: signal processing circuit, 500: RF coil portion, 501: RF coil portion, 510: saddle coil, 520: butterfly coil, 530: solenoid coil, 540: birdcage coil, 550: array coil, 610: QD coil, 611: first surface coil, 612: second surface coil, 621: first loop face, 622: second loop face, 631: magnetic field direction, 632: magnetic field direction, 641: phase adjustor, 642: synthesizer, 710: imaging sequence, 720: imaging sequence, 900: RF coil, 902: conductor, 904: cable, 910: capacitor, 911: capacitor, 920: inductor, 930: PIN diode, 950: magnetic coupling prevention circuit, 960: DC power supply

1. An RF coil of a magnetic resonance imaging device, the RF coil comprising:
a receiving antenna of receiving a control signal;
a switch circuit driven by the control signal received by the receiving antenna; and
a resonance circuit in which a capacitor is inserted to a loop comprising a conductor;
wherein the switch circuit is connected to the resonance circuit; and
wherein the resonance circuit differs in a resonance frequency by presence or absence of receiving the control signal.

2. The RF coil according to claim 1, wherein the switch circuit comprising:
a conversion circuit connected to the receiving antenna for converting the control signal received by the receiving antenna into a direct current voltage; and
switching means driven by the direct current voltage,
wherein the switch circuit is connected to the resonance circuit via the switching means.

3. The RF coil according to claim 1, further comprising:
a control signal generating circuit of generating the control signal at a previously determined timing; and
a transmitting antenna of transmitting the control signal generated by the control signal generating circuit.

4. The RF coil according to claim 1, wherein the loop includes two conductor loops arranged at a surface of a circular cylinder in correspondence with each other, and has a saddle shape in which the two conductor loops are connected such that directions of magnetic fields generated by the conductor loops are the same as each other.

5. The RF coil according to claim 1, wherein the loop includes two conductor loops arranged contiguous to each other in the same plane, and has a butterfly shape in which the two conductor loops are connected such that directions of magnetic fields generated by the conductor loops are inverse to each other.

6. The RF coil according to claim 1, wherein the loop has a solenoid shape.

7. The RF coil according to claim 1, wherein the loop has a birdcage shape.

8. The RF coil according to claim 1, wherein a plurality of the resonance circuits are included; and
wherein the plurality of resonance circuits are arranged on substantially the same face such that loop portions of the resonance circuits partially overlap each other.

9. The RF coil according to claim 1, wherein two of the resonance circuits are included;
wherein the two resonance circuits are arranged such that a direction of a magnetic field generated by one of the resonance circuits is orthogonal to a direction of a magnetic field generated at the other resonance circuit; and
wherein a phase of a radio frequency signal applied to one resonance circuit of the two resonance circuits differs from a phase of a radio frequency signal applied on the other resonance circuit by 90 degrees.

10. The RF coil according to claim 2, wherein the conversion circuit is a half-wave double voltage rectifier circuit of generating the direct current voltage by rectifying to smooth an alternating current voltage generated at the receiving antenna, and includes a rectifier element, a first capacitor, and a second capacitor;
wherein the rectifier element is configured by a series connection of a first rectifier diode and a second rectifier diode different polarity terminals of which are connected to each other;
wherein one terminal of the first capacitor is connected to a connection point at which the different polarity terminals of the first rectifier diode and the second rectifier diode are connected to each other;
wherein the other terminal of the first capacitor is connected to the receiving antenna; and
wherein the second capacitor is connected in parallel with the first rectifier diode and the second rectifier diode connected in series with each other.

11. The RF coil according to claim 2, wherein the converter circuit is a half-wave rectifier circuit generating the direct current voltage by rectifying to smooth an alternating current voltage generated at the receiving antenna, and includes a rectifier element and a capacitor;
wherein the rectifier element is configured by one rectifier diode or a series connection of a plurality of rectifier diodes aligning polarities thereof;
wherein one terminal of the rectifier diode is connected to the capacitor; and
wherein the other terminal of the rectifier diode is connected to the receiving antenna.

12. The RF coil according to claim 2, wherein the conversion circuit is a full-wave rectifier circuit of generating the direct current voltage by rectifying to smooth an alternating current voltage generated at the receiving antenna and includes a rectifier element and a capacitor;
wherein the rectifier element is configured by a bridge connection of rectifier diodes having an input side and output side;
wherein the input side of bridge connection of the rectifier diodes is connected to the receiving antenna; and
wherein the capacitor is connected to the output side of the bridge connection of the rectifier diodes.

13. The RF coil according to claim 3, wherein the control signal generating circuit generates the control signal in synchronism with an imaging sequence.

14. The RF coil according to claim 3, wherein the RF coil of transmitting a radio frequency signal serves also as the transmitting antenna.

15. The RF coil according to claim 1, wherein the resonance circuit is brought into an open state by a frequency of a magnetic resonance signal received by the magnetic resonance imaging device when the control signal is received.

16. An RF coil system of a magnetic resonance imaging device, the RF coil system comprising:
a transmit RF coil of transmitting a radio frequency signal; and
a receive RF coil of receiving a magnetic resonance signal;
wherein the receive RF coil is the RF coil according to claim 1; and
wherein the switch circuit brings the receive RF coil into an open state when the transmit RF coil transmits the radio frequency signal.

17. An RF coil system of a magnetic resonance imaging device, the RF coil system comprising:
a transmit RF coil of transmitting a radio frequency signal; and
a receive RF coil of receiving a magnetic resonance signal,
wherein the transmit RF coil is the RF coil according to claim 1, and
wherein the switch circuit brings the transmit RF coil into an open state when the receive RF coil receives the magnetic resonance signal.

18. A magnetic resonance imaging device comprising:
static magnetic field configuring means for configuring a static magnetic field;
gradient magnetic field applying means for applying a gradient magnetic field;
a transmit RF coil of transmitting a radio frequency signal;
a receive RF coil of receiving a magnetic resonance signal generated from a test subject by applying the radio frequency magnetic field; and
controlling means for controlling operations of the gradient magnetic field applying means, the transmit RF coil, and the receive RF coil,
wherein the receive RF coil is the RF coil according to claim 1.

19. A magnetic resonance imaging device comprising:
static magnetic field configuring means for configuring a static magnetic field;
gradient magnetic field applying means for applying a gradient magnetic field;
a transmit RF coil of transmitting a radio frequency signal, a receive RF coil of receiving a magnetic resonance signal generated from a test subject by applying the radio frequency magnetic field; and
controlling means for controlling operations of the gradient magnetic field applying means, the transmit RF coil, and the receive RF coil,
wherein the transmit RF coil is the RF coil according to claim 1.

20. A magnetic resonance imaging device comprising:
static magnetic field configuring means for configuring a static magnetic field;
gradient magnetic field applying means for applying a gradient magnetic field;
a transmit and receive RF coil of transmitting a radio frequency signal and receiving a magnetic resonance signal generated from a test subject by applying the radio frequency magnetic field; and
controlling means for controlling operations of the gradient magnetic field applying means and the transmit and receive RF coil,
wherein the transmit and receive RF coil is the RF coil according to claim 1.
